(19) United States
(12) Patent Application Publication
(10) Pub. No.: US 2026/0026225 A1
(43) Pub. Date: Jan. 22, 2026

(54) DISPLAY DEVICE AND ELECTRONIC DEVICE INCLUDING THE SAME

(71) Applicant: Samsung Display Co., LTD., Yongin-si (KR)

(72) Inventors: Se Hee KIM, Yongin-si (KR); Sun Jin JOO, Yongin-si (KR); Na Ri HEO, Yongin-si (KR); Sang Min HONG, Yongin-si (KR)

(21) Appl. No.: 19/075,566

(22) Filed: Mar. 10, 2025

(30) Foreign Application Priority Data
Jul. 18, 2024 (KR) 10-2024-0095024

(51) Int. Cl. H10K 59/38; H10K 59/122; H10K 59/80; H10K 102/00

(52) U.S. Cl. CPC H10K 59/38; H10K 59/8792; H10K 59/122; H10K 2102/351

(57) ABSTRACT

A display device and an electronic device including the display device are disclosed. The display device may include a display area including a first area and a second area around the first area, a non-display area around the display area, a light emitting element layer on the display area, including a pixel defining layer that partitions light emission areas, and a color filter layer in the first area and the second area on the light emitting element layer, including color filters and a light blocking pattern, wherein at least one selected from among the color filters in the second area may include a first portion protruded to overlap the light emission areas and a second portion around the first portion, and a thickness of an area of the color filters in the first area may be substantially the same as a thickness of the first portion.

### CROSS-REFERENCE TO RELATED APPLICATION

The present application claims priority to and the benefit of Korean Patent Application No. 10-2024-0095024, filed on Jul. 18, 2024, in the Korean Intellectual Property Office, the entire content of which is incorporated herein by reference.

### BACKGROUND

### 1. Field

One or more embodiments of the present disclosure relate to a display device and an electronic device including the display device.

### 2. Description of the Related Art

With the advancement of the information age, the demand for display devices to show images has increased in one or more suitable forms. For example, display devices are now used in a range of electronic devices, such as smartphones, digital cameras, laptop computers, navigators, and/or smart televisions.

Display devices may be flat panel displays, such as liquid crystal displays (LCDs), field emission displays (FEDs), and/or light-emitting displays (LEDs). Light-emitting displays include organic light-emitting displays (OLEDs) that use organic light-emitting elements, inorganic light-emitting displays that use inorganic light-emitting elements like inorganic semiconductors, and micro light-emitting displays that use micro light-emitting elements.

An organic light emitting element may include two electrodes opposite to (e.g., facing) each other and a light emitting layer positioned between the electrodes. The light emitting layer may generate excitons through the recombination of electrons and holes received from the electrodes, and these excitons transition from an excited state to a ground state to emit light.

Organic light-emitting display devices, which incorporate organic light-emitting elements, do not require a light source such as a backlight unit. As a result, they offer high-quality characteristics, including a wide viewing angle, high luminance and contrast, fast response speed, low power consumption, and a lightweight and thin profile. Consequently, organic light-emitting display devices are recognized as next-generation display devices.

### SUMMARY

One or more aspects of embodiments of the present disclosure are directed toward a display device that may improve or enhance display quality.

Additional aspects of embodiments will be set forth in part in the description which follows and, in part, will be apparent from the description or may be learned by practice of the presented embodiments of the disclosure.

One or more embodiments of the present disclosure provide a display device that includes a display area including a first area and a second area around (e.g., surrounding) the first area, a non-display area around (e.g., surrounding) the display area, a light emitting element layer on the display area, including a pixel defining layer that partitions light emission areas, and a color filter layer in the first area and the second area on the light emitting element layer, including color filters and a light blocking pattern, wherein at least one selected from among the color filters in the second area includes a first portion protruded to overlap the light emission areas and a second portion around (e.g., surrounding) the first portion, and a thickness of an area of the color filters in the first area, which overlaps the light emission areas, is substantially the same as a thickness of the first portion.

In one or more embodiments, the first area may correspond to a central portion of the display area, and the second area may correspond to an edge of the display area.

In one or more embodiments, a width of the second area, which is measured in one direction, may be about 1% to about 8% of a width of the display area, which is measured in the one direction.

In one or more embodiments, the first portion may be more protruded than the second portion in a thickness direction, and a thickness of the first portion may be greater than a thickness of the second portion.

In one or more embodiments, the first portion may not overlap the pixel defining layer and the light blocking pattern.

In one or more embodiments, the second portion may not overlap the light emission areas but may overlap the pixel defining layer and the light blocking pattern.

In one or more embodiments, each of the color filters in the second area may include the first portion and the second portion, and each of the first portions may have substantially the same thickness.

In one or more embodiments, the light blocking pattern may partition light output portions that correspond to the light emission areas, the first portion may overlap the light output portions, and the second portion may not overlap the light output portions.

In one or more embodiments, the first portion may overlap the pixel defining layer but may not overlap the light blocking pattern, and the second portion may overlap the light blocking pattern and the pixel defining layer.

In one or more embodiments, the at least one selected from among the color filters in the second area may be different in thickness from another one selected from among the color filters in the second area.

In one or more embodiments, the color filters in the second area may include a first color filter, a second color filter, and a third color filter, which may be to transmit light of different colors, each of the second color filter and the third color filter may include the first portion and the second portion, and the first color filter may not include the first portion and the second portion.

In one or more embodiments, a thickness of the first portion of the second color filter or a thickness of the first portion of the third color filter may be greater than a thickness of the first color filter.

In one or more embodiments, the thickness of the first portion of the second color filter and the thickness of the first portion of the third color filter may be substantially the same as each other. In one or more embodiments, the thickness of the first portion of the second color filter may be substantially the same as the thickness of the first portion of the third color filter.

In one or more embodiments, a thickness of the first portion of the second color filter may be greater than a thickness of the first portion of the third color filter.

One or more embodiments of the present disclosure provide a display device that includes a display area including a first area and a second area around (e.g., surrounding) the first area, a non-display area around (e.g., surrounding) the display area, a light emitting element layer on the display area, and a color filter layer in the first area and the second area on the light emitting element layer, including color filters and a light blocking pattern, wherein the light blocking pattern partitions light output portions through which light is output from the light emitting element layer, at least one selected from among the color filters in the second area includes a first portion that overlaps the light output portions and a second portion that has a thickness smaller than a thickness of the first portion, and a thickness of an area of the color filters in the first area, which overlaps the light output portions, is substantially the same as the thickness of the first portion.

In one or more embodiments, the first portion may not overlap the light blocking pattern, and the second portion may overlap the light blocking pattern.

In one or more embodiments, the first area may correspond to a central portion of the display area, and the second area may correspond to an edge of the display area.

In one or more embodiments, each of the color filters in the second area may include the first portion and the second portion, and each of the first portions may have substantially the same thickness.

In the display device according to one or more embodiments, a luminance difference between a first area that corresponds to a central portion of a display area and a second area that corresponds to an edge of the display area may be substantially resolved. Also, a white color in the second area that corresponds to the edge of the display area may be improved or enhanced. For example, a luminance difference between the first area (central portion) and the second area (edge) of the display area may be substantially resolved or addressed. For example, the luminance difference between the central portion and the edge of the display area may be reduced, minimized, or eliminated, resulting in a more uniform display quality across the entire screen. In one or more embodiments, the white color in the second area (edge) of the display area may be improved or enhanced.

One or more embodiments of the present disclosure provide an electronic device that includes the display device as described in one or more embodiments.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

The aspects and features of embodiments of the present disclosure are not limited to those mentioned above, and one or more suitable aspects and features are included in the following description of the present disclosure.

### BRIEF DESCRIPTION OF THE DRAWINGS

The above and other aspects and features of certain embodiments of the present disclosure will become more apparent and more readily appreciated from the following description of one or more embodiments, taken in conjunction with the accompanying drawings, in which:

FIG. 1 is a schematic perspective view illustrating an electronic device according to one or more embodiments;

FIG. 2 is a perspective view illustrating a folding state of a foldable display device according to one or more embodiments;

FIG. 3 is a perspective view illustrating an unfolding state of a foldable display device of FIG. 2;

FIG. 4 is a perspective view illustrating a display device in an electronic device according to one or more embodiments;

FIG. 5 is a cross-sectional view illustrating a display device of FIG. 4, which is viewed from a side;

FIG. 6 is a plan view illustrating a display layer of a display device according to one or more embodiments;

FIG. 7 is a plan view illustrating a touch sensing layer of a display device according to one or more embodiments;

FIG. 8 is a plan view illustrating arrangement of light emission areas in a display area of a display device according to one or more embodiments;

FIG. 9 is a plan view illustrating arrangement of color filters in a display area of FIG. 8;

FIG. 10 is a cross-sectional view taken along the line X1-X1′ of FIG. 9;

FIG. 11 is a schematic plan view illustrating a display device according to one or more embodiments;

FIG. 12 is a cross-sectional view taken along the lines X2-X2′ and X3-X3′ of FIG. 11;

FIG. 13 is a view illustrating a second light emission area of a first area and a first light emission area, a second light emission area, and a third light emission area of a second area in a display area of FIG. 12;

FIG. 14 is an enlarged view illustrating a first color filter of a second area of FIG. 13;

FIGS. 15-21 each is a cross-sectional view for each process of a display device according to one or more embodiments;

FIG. 22 is a schematic cross-sectional view illustrating a display device according to one or more embodiments;

FIG. 23 is a view illustrating a second light emission area of a first area and a first light emission area, a second light emission area, and a third light emission area of a second area in a display area of FIG. 22; and

FIGS. 24-27 each is a schematic cross-sectional view illustrating examples of a display device according to one or more embodiments.

### DETAILED DESCRIPTION

The subject matter of the present disclosure will be described more fully hereinafter with reference to the accompanying drawings, in which embodiments of present disclosure are illustrated. The subject matter of the present disclosure may, however, be embodied in one or more forms and should not be construed as being limited to one or more embodiments set forth herein, and one or more changes and modifications may be made. Rather, these embodiments are provided as examples so that this disclosure will be thorough and complete and will fully convey the aspects and features of the present disclosure to those skilled in the art to which the present disclosure pertains.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will also be understood that if (e.g., when) a layer is referred to as being “on” another layer or substrate, it may be directly on the other layer or substrate, or intervening layers may also be present.

The same reference numbers refers to substantially the same components throughout the specification.

It will be understood that, although the terms “first,” “second,” and/or the like may be used herein to describe one or more suitable elements, these elements should not be limited by these terms. These terms are only used to distinguish one element from another element. For instance, a first element discussed may be termed a second element without departing from the teachings of the present disclosure. Similarly, the second element may also be termed the first element.

A person of ordinary skill in the art, in view of the present disclosure in its entirety, would appreciate that each suitable feature of the one or more embodiments of the present disclosure may be combined or combined with each other, in part or in whole, and may be technically interlocked and operated in one or more suitable ways, and each embodiment may be implemented independently of each other or in conjunction with each other in any suitable manner unless otherwise state or implied.

Hereinafter, embodiments of the present disclosure will be described with reference to the accompanying drawings.

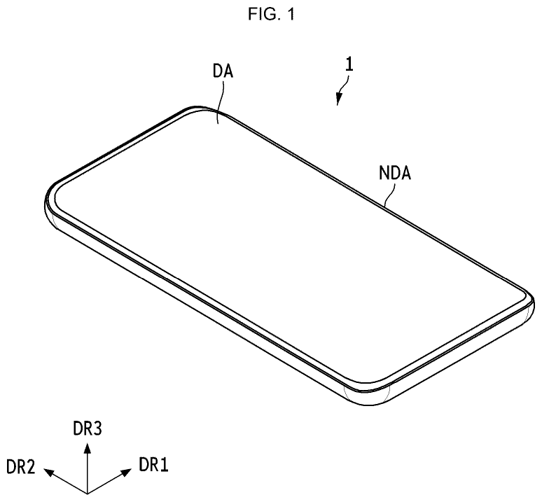

FIG. 1 is a schematic perspective view illustrating an electronic device according to one or more embodiments.

Referring to FIG. 1, an electronic device 1 may display a moving image and/or a still image. The electronic device 1 may be referred to as all electronic devices that provide a display screen. For example, a television, a laptop computer, a monitor, an advertising board, Internet of Things, a mobile phone, a smart phone, a tablet personal computer (PC), an electronic watch, a smart watch, a watch phone, a head mounted display, a mobile communication terminal, an electronic diary, an electronic book, a portable multimedia player (PMP), a navigator, a game machine, a digital camera, a camcorder, and/or the like, which provide a display screen, may be in the electronic device 1.

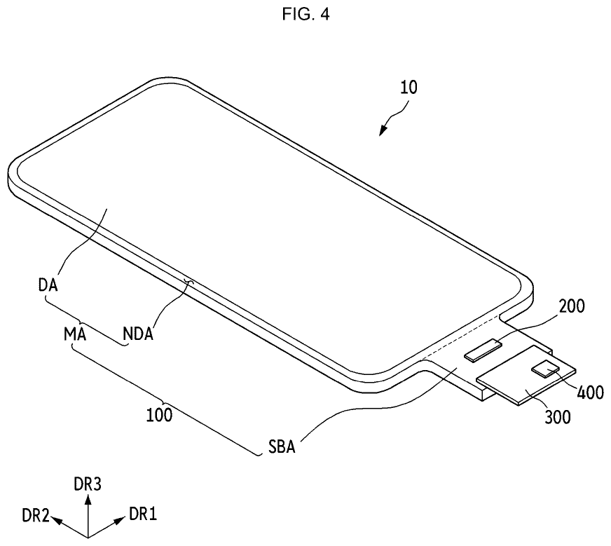

Examples of the electronic device 1 may include a display device (10 of FIG. 4) that provides a display screen. Examples of the display device may include an inorganic light emitting diode display device, an organic light emitting display device, a quantum dot light emitting display device, a plasma display device, and/or a field emission display device. The following description will be based on that an organic light emitting display device is applied as an example of the display device, but embodiments of the present disclosure are not limited thereto, and another display device may be applied to the display device 1 within the range that substantially the same technical spirits are applicable thereto.

One or more modifications may be made in a shape of the electronic device 1. For example, the electronic device 1 may have a shape, such as a rectangle (e.g., substantially rectangle) of a long width, a rectangle (e.g., substantially rectangle) of a long length, a square (e.g., a substantially square), a rectangle (e.g., substantially rectangle) of round corners (e.g., vertexes), other polygons (e.g., substantially polygons), and a circle (e.g., a substantially circle). A shape of a display area DA of the electronic device 1 may be also substantially similar to an overall shape of the electronic device 1. A rectangular electronic device 1, in which a length in a second direction DR2 is longer, is illustrated in FIG. 1.

The electronic device 1 may include a display area DA and a non-display area NDA. The display area DA may be an area in which a screen may be displayed, and the non-display area NDA may be an area in which a screen is not displayed. The display area DA may be referred to as an active area, and the non-display area NDA may be referred to as a non-active area. The display area DA may occupy the center of the electronic device 1.

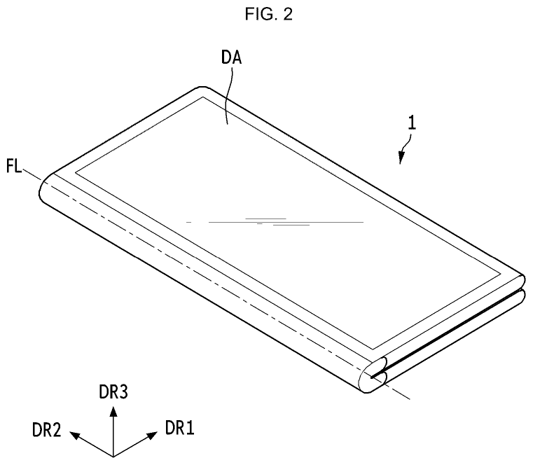

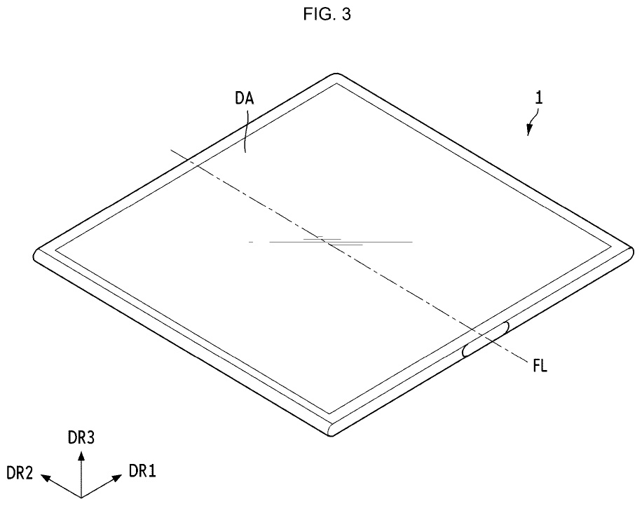

FIG. 2 is a perspective view illustrating a folding state of a foldable display device according to one or more embodiments. FIG. 3 is a perspective view illustrating an unfolding state of a foldable display device of FIG. 2.

Referring to FIGS. 2 and 3, the electronic device 1 according to one or more embodiments may be a foldable display device. The foldable electronic device 1 may be folded around (e.g., surrounding) a folding axis FL. The display area DA may be outside and/or inside the foldable electronic device 1. In one or more embodiments, the foldable electronic device 1 of FIGS. 2 and 3 is illustrated in which the display area DA may be outside and inside.

The display area DA may be outside the electronic device 1. An outer side of the electronic device 1 which is folded may include the display area DA, and an inner side of the electronic device 1 which is unfolded may include the display area DA.

FIG. 4 is a perspective view illustrating a display device in an electronic device according to one or more embodiments.

Referring to FIG. 4, the electronic device 1 according to one or more embodiments may include a display device 10. The display device 10 may provide a screen displayed by the electronic device 1. The display device 10 may have a planar shape (e.g., a substantially planar shape) substantially similar to that of the electronic device 1. For example, the display device 10 may have a shape substantially similar to a rectangle (a substantially rectangle) that has a short side in a first direction DR1 and a long side in the second direction DR2. A corner at which the short side in the first direction DR1 and the long side in the second direction DR2 meet may be formed or provided to be rounded to have a curvature but may be formed or provided at a right angle without being limited thereto. The planar shape (e.g., the substantially planar shape) of the display device 10 may be formed or provided to be substantially similar to another polygonal shape (e.g., substantially polygonal shape), a circular shape (e.g., a substantially circular shape), or an oval shape (e.g., a substantially oval shape) without being limited to the rectangle (e.g., the substantially rectangle).

The display device 10 may include a display panel 100, a display driver 200, a circuit board 300, and a touch driver 400.

The display panel 100 may include a main area MA and a sub-area SBA.

The main area MA may include a display area DA including pixels to display an image and a non-display area NDA near the display area DA. The display area DA may be to emit light from a plurality of light emission areas or a plurality of opening areas. For example, the display panel 100 may include a pixel circuit including switching elements, a pixel defining layer that defines a light emission area or an opening area, and a self-light emitting element.

For example, the self-light emitting element may include at least one of an organic light emitting diode including an organic light emitting layer, a quantum dot light emitting diode (LED) including a quantum dot light emitting layer, an inorganic light emitting diode (inorganic LED) including an inorganic semiconductor, or a micro light emitting diode (micro LED), but embodiments of the present disclosure are not limited thereto.

The non-display area NDA may be an outer area of the display area DA. The non-display area NDA may be defined as an edge area of the main area MA of the display panel 100. The non-display area NDA may include a gate driver that supplies gate signals to gate lines, and fan-out lines that connects the display driver 200 with (or to) the display area DA.

The sub-area SBA may be an area extended from one side of the main area MA. The sub-area SBA may include a flexible material capable of being subjected to bending, folding, rolling and/or the like. For example, if (e.g., when) the sub-area SBA is bent, the sub-area SBA may overlap the main area MA in a thickness direction (e.g., a third direction DR3). The sub-area SBA may include a display driver 200 and a pad portion connected to the circuit board 300. In one or more embodiments, the sub-area SBA may not be provided, and the display driver 200 and the pad portion may be in the non-display area NDA. Also, in the present context and unless defined otherwise, a plan view refers to a top-down view in the third direction DR3, illustrating the layout of these components as seen from above, focusing on their arrangement and spatial relationships in the plane substantially parallel to a plane defined by the first and second directions DR1 and DR2.

The display driver 200 may be to output signals and voltages to drive the display panel 100. The display driver 200 may be to supply data voltages to data lines. The display driver 200 may be to supply a power voltage to a power line and may be to supply a gate control signal to a gate driver. The display driver 200 may be of an integrated circuit (IC) and may be packaged on the display panel 100 by a chip on glass (COG) mode, a chip on plastic (COP) mode, or an ultrasonic bonding mode. For example, the display driver 200 may be in the sub-area SBA and may overlap the main area MA in the thickness direction by bending of the sub-area SBA. For another example, the display driver 200 may be packaged on the circuit board 300.

The circuit board 300 may be attached onto the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film, such as a chip on film.

The touch driver 400 may be packaged on the circuit board 300. The touch driver 400 may be connected to a touch sensing unit of the display panel 100. The touch driver 400 may be to supply a touch driving signal to a plurality of touch electrodes of the touch sensing unit and may be to sense a change amount of capacitance between the plurality of touch electrodes. For example, the touch driving signal may be a pulse signal that has a set or predetermined frequency. The touch driver 400 may be to calculate whether to input and input coordinates based on the change amount of capacitance between the plurality of touch electrodes. The touch driver 400 may be of an integrated circuit (IC).

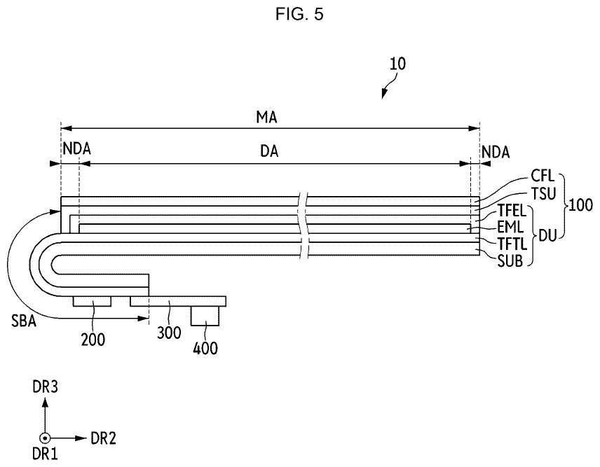

FIG. 5 is a cross-sectional view illustrating a display device of FIG. 4, which is viewed from a side.

Referring to FIG. 5, the display panel 100 may include a display layer DU, a touch sensing layer TSU, and a color filter layer CFL. The display layer DU may include a substrate SUB, a thin film transistor layer TFTL, a light emitting element layer EML, and an encapsulation layer TFEL.

The substrate SUB may be a base substrate or a base member. The substrate SUB may be a flexible substrate capable of being subjected to bending, folding, rolling, and/or the like. For example, the substrate SUB may contain a polymer resin, such as polyimide (PI), but embodiments of the present disclosure are not limited thereto. In one or more embodiments, the substrate SUB may contain a glass material and/or a metal material.

The thin film transistor layer TFTL may be on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor area, a source electrode, a drain electrode, and a gate electrode. For example, if (e.g., when) the gate driver is on one side of the non-display area NDA of the display panel 100, the gate driver may include thin film transistors.

The thin film transistor layer TFTL may be in the display area DA, the non-display area NDA, and the sub-area SBA. The thin film transistors, the gate lines, the data lines, and the power lines of the pixels of the thin film transistor layer TFTL may be in the display area DA. The gate control lines and the fan-out lines of the thin film transistor layer TFTL may be in the non-display area NDA. The lead lines of the thin film transistor layer TFTL may be in the sub-area SBA.

The light emitting element layer EML may be on the thin film transistor layer TFTL. The light emitting element layer EML may include a plurality of light emitting elements that include a pixel electrode, a common electrode, and a light emitting layer to emit light, and a pixel defining layer to define pixels. The plurality of light emitting elements of the light emitting element layer EML may be in the display area DA.

In one or more embodiments, the light emitting layer may be an organic light emitting layer that includes an organic material. The light emitting layer may include a hole transporting layer, an organic light emitting layer, and an electron transporting layer. If (e.g., when) the pixel electrode receives a voltage through the thin film transistor of the thin film transistor layer TFTL and the common electrode receives a cathode voltage, holes and electrons may move to the organic light emitting layer through the hole transporting layer and the electron transporting layer, respectively, and may be combined with each other in the organic light emitting layer to emit light.

In one or more embodiments, the light emitting element may include a quantum dot light emitting diode including a quantum dot light emitting layer, an inorganic light emitting diode including an inorganic semiconductor, and/or a micro light emitting diode.

The encapsulation layer TFEL may cover an upper surface and a side of the light emitting element layer EML and may protect the light emitting element layer EML. The encapsulation layer TFEL may include at least one inorganic layer and at least one organic layer to encapsulate the light emitting element layer EML.

The touch sensing layer TSU may be on the encapsulation layer TFEL. The touch sensing layer TSU may include a plurality of touch electrodes to sense a user's touch in a capacitance manner, and touch lines to connect the plurality of touch electrodes with (or to) the touch driver 400. For example, the touch sensing layer TSU may sense a user's touch in a mutual capacitance manner and/or a self-capacitance manner.

In one or more embodiments, the touch sensing layer TSU may be on a separate substrate that is on the display layer DU. In one or more embodiments, the substrate that supports the touch sensing layer TSU may be a base member to encapsulate the display layer DU.

The plurality of touch electrodes of the touch sensing layer TSU may be in a touch sensor area that overlaps the display area DA. The touch lines of the touch sensing layer TSU may be in a touch peripheral area that overlaps the non-display area NDA.

The color filter layer CFL may be on the touch sensing layer TSU. The color filter layer CFL may include a plurality of color filters respectively that correspond to the plurality of light emission areas. Each of the color filters may be to selectively transmit light of a set or specific wavelength and to block or absorb light of another wavelength. The color filter layer CFL may be to absorb a portion of light incident from the outside of the display device 10 to reduce reflective light due to external light. Therefore, the color filter layer CFL may prevent color distortion (or reduce a degree or occurrence of color distortion) due to reflection of the external light.

As the color filter layer CFL is directly on the touch sensing layer TSU, the display device 10 may not need a separate substrate for the color filter layer CFL. Therefore, a thickness of the display device 10 may be relatively small.

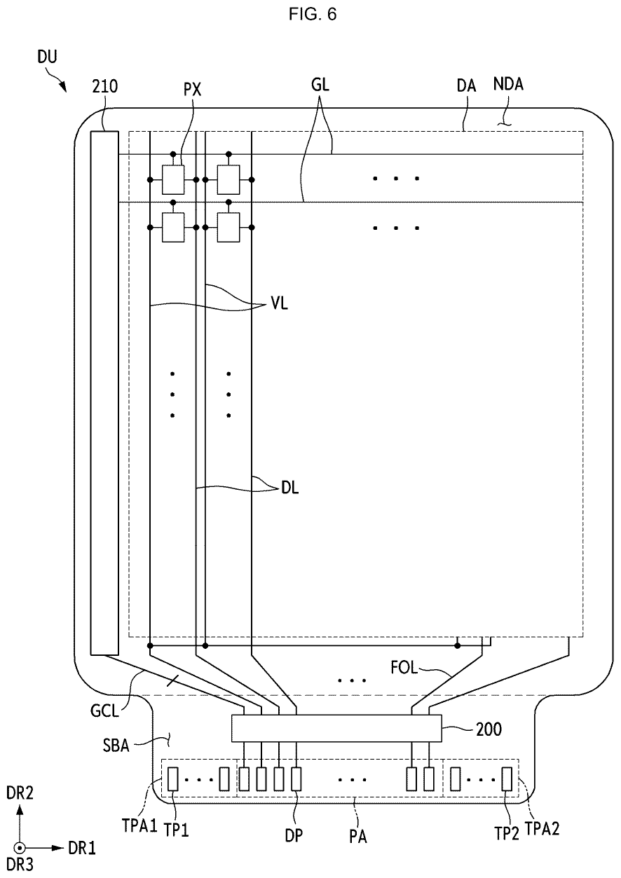

FIG. 6 is a plan view illustrating a display layer of a display device according to one or more embodiments.

Referring to FIG. 6, the display layer DU may include a display area DA and a non-display area NDA.

The display area DA may be at the center of the display panel 100. A plurality of pixels PX, a plurality of gate lines GL, a plurality of data lines DL, and a plurality of power lines VL may be in the display area DA. Each of the plurality of pixels PX may be defined as a minimum unit to emit light.

The plurality of gate lines GL may be to supply the gate signals received from a gate driver 210 to the plurality of pixels PX. The plurality of gate lines GL may be extended in the first direction DR1 and may be spaced and/or apart (e.g., spaced apart or separated) from each other in the second direction DR2 that crosses the first direction DR1.

The plurality of data lines DL may be to supply the data voltages received from the display driver 200 to the plurality of pixels PX. The plurality of data lines DL may be extended in the second direction DR2 and may be spaced and/or apart (e.g., spaced apart or separated) from each other in the first direction DR1.

The plurality of power lines VL may be to supply the power voltage received from the display driver 200 to the plurality of pixels PX. In one or more embodiments, the power voltage may be at least one of a driving voltage, an initialization voltage, a reference voltage, or a low potential voltage. The plurality of power lines VL may be extended in the second direction DR2 and may be spaced and/or apart (e.g., spaced apart or separated) from each other in the first direction DR1.

The non-display area NDA may be around (e.g., surround) the display area DA. The gate driver 210, fan-out lines FOL, and gate control lines GCL may be in the non-display area NDA. The gate driver 210 may be to generate a plurality of gate signals based on the gate control signals and may be to sequentially supply the plurality of gate signals to the plurality of gate lines GL in accordance with a set or predetermined order.

The fan-out lines FOL may be extended from the display driver 200 to the display area DA. The fan-out lines FOL may be to supply the data voltages received from the display driver 200 to the plurality of data lines DL.

The gate control line GCL may be extended from the display driver 200 to the gate driver 210. The gate control line GCL may be to supply the gate control signals received from the display driver 200 to the gate driver 210.

The sub-area SBA may include a display driver 200, a pad area DPA, a first touch pad area TPA1, and a second touch pad area TPA2.

The display driver 200 may be to output signals and voltages to drive the display panel 100 to the fan-out lines FOL. The display driver 200 may be to supply the data voltages to the data lines DL through the fan-out lines FOL. The data voltages may be supplied to the plurality of pixels PX and may be to control luminance of the plurality of pixels PX. The display driver 200 may be to supply the gate control signals to the gate driver 210 through the gate control line GCL.

The pad area PA, the first touch pad area TPA1, and the second touch pad area TPA2 may be at an edge of the sub-area SBA. The pad area PA, the first touch pad area TPA1, and the second touch pad area TPA2 may electrically be connected to the circuit board 300 by using a material, such as an anisotropic conductive film and/or a self-assembly anisotropic conductive paste (SAP). The first touch pad area TPA1 may include a first touch pad portion TP1, and the second touch pad area TPA2 may include a second touch pad portion TP2, whereby the first touch pad area and the second touch pad area may be electrically connected to the circuit board 300.

The pad area PA may include a plurality of display pad portions DP. The plurality of display pad portions DP may be connected to a graphic system through the circuit board 300. The plurality of display pad portions DP may be connected to the circuit board 300 to receive digital video data and may be to supply the digital video data to the display driver 200.

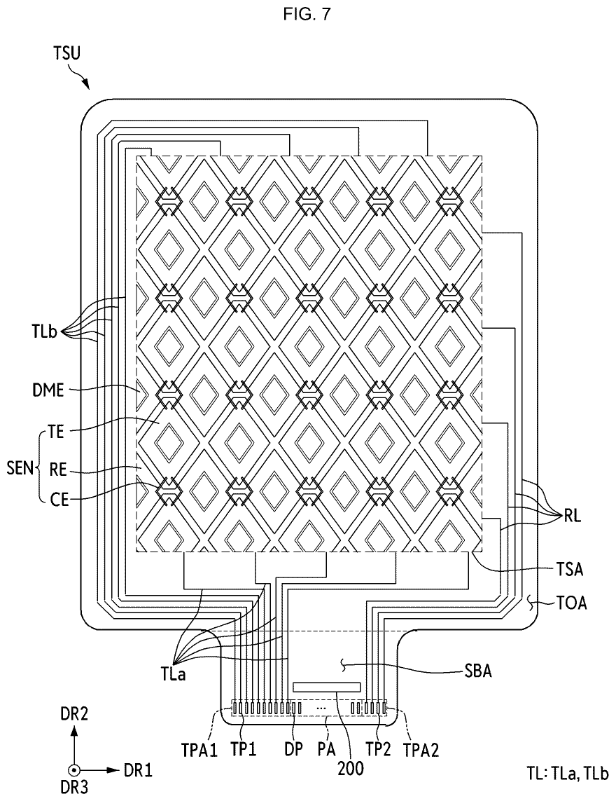

FIG. 7 is a plan view illustrating a touch sensing layer of a display device according to one or more embodiments.

Referring to FIG. 7, the touch sensing layer TSU may include a touch sensor area TSA to sense a user's touch and a touch peripheral area TOA near the touch sensor area TSA. The touch sensor area TSA may be in the display area DA of the display device 10, and the touch peripheral area TOA may be in the non-display area NDA of the display device 10.

The touch sensor area TSA may include a plurality of touch electrodes SEN and a plurality of dummy electrodes DME. The plurality of touch electrodes SEN may form or provide mutual capacitance and/or self-capacitance to sense a touch of an object and/or a person. The plurality of touch electrodes SEN may include a plurality of driving electrodes TE, a plurality of sensing electrodes RE, and a bridge electrode CE.

The plurality of driving electrodes TE may be in the first direction DR1 and the second direction DR2. The plurality of driving electrodes TE may be spaced and/or apart (e.g., spaced apart or separated) from each other in the first direction DR1 and the second direction DR2. The driving electrodes TE adjacent to each other in the second direction DR2 may be electrically connected to each other through the bridge electrode CE.

The plurality of driving electrodes TE may be connected to the first touch pad portion TP1 through a driving line TL. The driving line TL may include a lower driving line TLa and an upper driving line TLb. For example, the driving electrodes TE below the touch sensor area TSA may be connected to the first touch pad portion TP1 through the lower driving line TLa, and the driving electrodes TE above the touch sensor area TSA may be connected to the first touch pad portion TP1 through the upper driving line TLb. The lower driving line TLa may be extended to the first touch pad portion TP1 by passing through a lower side of the touch peripheral area TOA. The upper driving line TLb may be extended to the first touch pad portion TP1 by passing through upper, left, and lower sides of the touch peripheral area TOA. The first touch pad portion TP1 may be connected to the touch driver 400 through the circuit board 300.

The bridge electrode CE may be bent at least once. For example, the bridge electrode CE may have a clamp shape (e.g., a substantially clamp shape), such as “<” or “>”, a planar shape (e.g., a substantially planar shape) of the bridge electrode CE is not limited thereto. The driving electrodes TE adjacent to each other in the second direction DR2 may be connected to each other by the plurality of bridge electrodes CE, and even though any one selected from among the bridge electrodes CE is disconnected, the driving electrodes TE may be stably connected to each other through the other bridge electrodes CE. The driving electrodes TE adjacent to each other may be connected by two bridge electrodes CE, but the number of the bridge electrodes CE is not limited thereto.

The bridge electrode CE may be on a different layer from the plurality of driving electrodes TE and the plurality of sensing electrodes RE. The sensing electrodes RE adjacent to each other in the first direction DR1 may be electrically connected to each other through a connection portion on substantially the same layer as the plurality of driving electrodes TE or the plurality of sensing electrodes RE. The driving electrodes TE adjacent to each other in the second direction DR2 may be electrically connected to each other through the bridge electrode CE on a different layer from the plurality of driving electrodes TE or the plurality of sensing electrodes RE. Therefore, even though the bridge electrode CE overlaps the plurality of sensing electrodes RE in a Z-axis direction, the plurality of driving electrodes TE and the plurality of sensing electrodes RE may be insulated from each other. Mutual capacitance may be between the driving electrode TE and the sensing electrode RE.

The plurality of sensing electrodes RE may be extended in the first direction DR1 and may be spaced and/or apart (e.g., spaced apart or separated) from each other in the second direction DR2. The plurality of sensing electrodes RE may be in the first direction DR1 and the second direction DR2, and the sensing electrodes RE adjacent to each other in the first direction DR1 may be electrically connected to each other through the connection portion.

The plurality of sensing electrodes RE may be connected to the second touch pad portion TP2 through a sensing line RL. For example, the sensing electrodes RE on a right side of the touch sensor area TSA may be connected to the second touch pad portion TP2 through the sensing line RL. The sensing line RL may be extended to the second touch pad portion TP2 through right and lower sides of the touch peripheral area TOA. The second touch pad portion TP2 may be connected to the touch driver 400 through the circuit board 300.

Each of the plurality of dummy electrodes DME may be surrounded by the driving electrode TE or the sensing electrode RE. Each of the plurality of dummy electrodes DME may be insulated from the driving electrode TE or the sensing electrode RE by being spaced and/or apart (e.g., spaced apart or separated) therefrom. Therefore, the dummy electrode DME may be electrically floated.

The pad area PA, the first touch pad area TPA1, and the second touch pad area TPA2 may be at the edge of the sub-area SBA. The pad area PA, the first touch pad area TPA1, and the second touch pad area TPA2 may be electrically connected to the circuit board 300 by using a low-resistance and high-reliability material, such as an anisotropic conductive film and/or a self-assembly anisotropic conductive paste (SAP).

The first touch pad area TPA1 may be on one side of the pad area PA and may include a plurality of first touch pad portions TP1. The plurality of first touch pad portions TP1 may be electrically connected to the touch driver 400 on the circuit board 300. The plurality of first touch pad portions TP1 may be to supply the touch driving signal to the plurality of driving electrodes TE through the plurality of driving lines TL.

The second touch pad area TPA2 may be on the other side of the pad area PA and may include a plurality of second touch pad portions TP2. The plurality of second touch pad portions TP2 may be electrically connected to the touch driver 400 on the circuit board 300. The touch driver 400 may be to receive a touch sensing signal through the plurality of sensing lines RL connected to the plurality of second touch pad portions TP2 and may be to sense a change in mutual capacitance between the driving electrode TE and the sensing electrode RE.

In one or more embodiments, the touch driver 400 may be to supply the touch driving signal to each of the plurality of driving electrodes TE and the plurality of sensing electrodes RE and may be to receive the touch sensing signal from each of the plurality of driving electrodes TE and the plurality of sensing electrodes RE. The touch driver 400 may be to sense a charge change amount of each of the plurality of driving electrodes TE and the plurality of sensing electrodes RE based on the touch sensing signal.

In FIG. 7, the plurality of touch electrodes SEN of the touch sensing layer TSU may be in a structure of a diamond shape (e.g., a substantially diamond shape) and connected in the first direction DR1 and the second direction DR2, but embodiments of the present disclosure are not limited thereto. The plurality of touch electrodes SEN may be in a mesh shape (e.g., a substantially mesh shape).

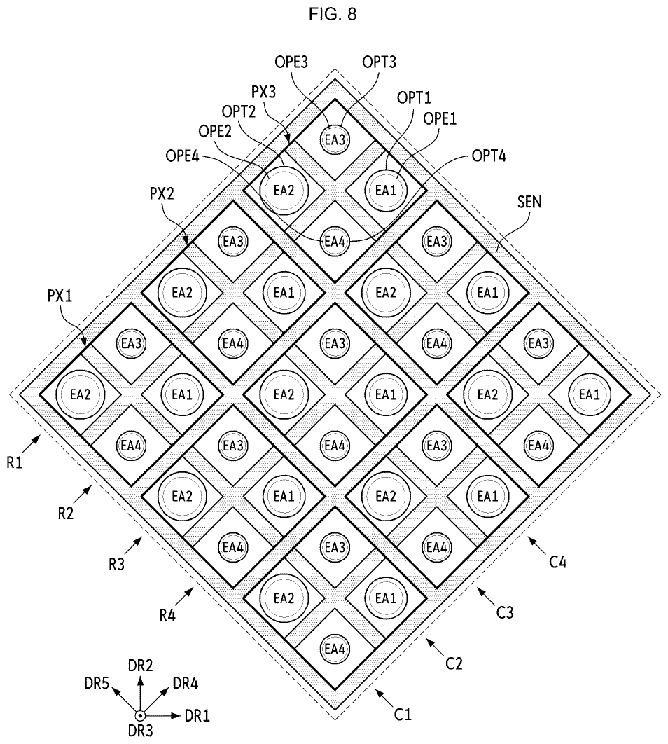

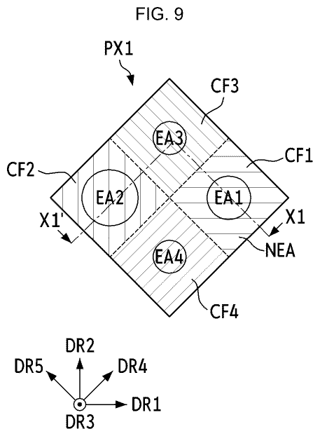

FIG. 8 is a plan view illustrating arrangement of light emission areas in a display area of a display device according to one or more embodiments. FIG. 9 is a plan view illustrating arrangement of color filters in a display area of FIG. 8.

Referring to FIGS. 8 and 9, the display device 10 may include a plurality of pixels PX1, PX2, and PX3 in the display area DA, and light emission areas EA1, EA2, EA3, and EA4 and a non-light emission area NEA, which are in each of the pixels PX1, PX2, and PX3. The plurality of pixels PX1, PX2, and PX3 may be in the fourth direction DR4 and the fifth direction DR5 between the first direction DR1 and the second direction DR2. The first pixel PX1, the second pixel PX2, and the third pixel PX3 may be alternately arranged or provided along the fourth direction DR4 and the fifth direction DR5. For example, the second pixel PX2 and the third pixel PX3 may be along the fourth direction DR4 and the fifth direction DR5 based on the first pixel PX1. The plurality of pixels PX1, PX2, and PX3 may be in the display area DA in a PenTile™ type (kind), for example, a diamond PenTile™ type (kind). However, the arrangement or array of the pixels PX1, PX2, and PX3 is not limited to that illustrated in FIGS. 8 and 9. In one or more embodiments, the plurality of pixels PX1, PX2, and PX3 may be in a linear (e.g., a substantially linear) pattern or an island-shaped (e.g., a substantially island-shaped) pattern.

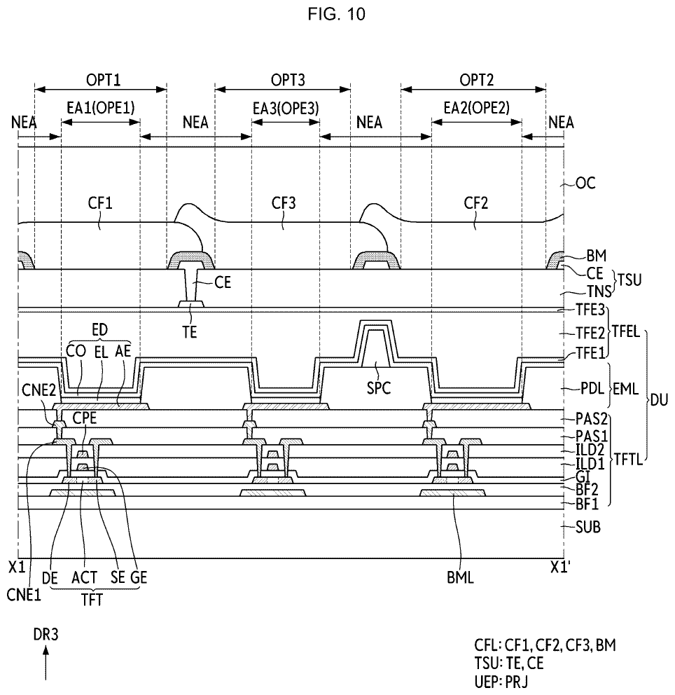

The light emission areas EA1, EA2, EA3, and EA4 of each of the pixels PX1, PX2, and PX3 may include a first light emission area EA1, a second light emission area EA2, a third light emission area EA3, and a fourth light emission area EA4, which may be to emit light of different colors. Unlike the first light emission area EA1 and the second light emission area EA2, the third light emission area EA3 and the fourth light emission area EA4 may be to emit light of substantially the same color. Each of the first light emission area EA1, the second light emission area EA2, the third light emission area EA3, and the fourth light emission area EA4 may be to emit light of red, blue, or green, and the color of light emitted from each of the light emission areas EA1, EA2, EA3, and EA4 may be different depending on the type (kind) of a light emitting element (‘ED’ of FIG. 10) in the light emitting element layer EML that will be described in more detail later. In one or more embodiments, the first light emission area EA1 may be to emit first light of a red color, the second light emission area EA2 may be to emit second light of a blue color, and the third light emission area EA3 and the fourth light emission area EA4 may be to emit third light of a green color, but embodiments of the present disclosure are not limited thereto.

The plurality of light emission areas EA1, EA2, EA3, and EA4 may be in a PenTile™ type (kind), for example, a diamond PenTile™ type (kind). For example, in each of the pixels PX1, PX2, and PX3, the first light emission area EA1 and the second light emission area EA2 may be to be spaced and/or apart (e.g., spaced apart or separated) from each other in the first direction DR1, and the third light emission area EA3 and the fourth light emission area EA4 may be to be spaced and/or apart (e.g., spaced apart or separated) from each other in the second direction DR2. The first light emission area EA1 may be to be spaced and/or apart (e.g., spaced apart or separated) from the third light emission area EA3 in the fifth direction DR5 and may be to be spaced and/or apart (e.g., spaced apart or separated) from the fourth light emission area EA4 in the fourth direction DR4. The second light emission area EA2 may be to be spaced and/or apart (e.g., spaced apart or separated) from the third light emission area EA3 in the fourth direction DR4 and may be to be spaced and/or apart (e.g., spaced apart or separated) from the fourth light emission area EA4 in the fifth direction DR5.

In the plurality of pixels PX1, PX2, and PX3, the plurality of the first light emission area EA1, the second light emission area EA2, the third light emission area EA3, and the fourth light emission area EA4 may be alternately arranged or provided in the fourth direction DR4 or the fifth direction DR5. For example, the plurality of light emission areas EA1, EA2, EA3, and EA4 may be in rows R1, R2, R3, and R4 that are along the fourth direction DR4 and columns C1, C2, C3, and C4 that are along the fifth direction DR5. In the first row R1 and the third row R3, the second light emission area EA2 and the third light emission area EA3 may be alternately arranged or provided along the fourth direction DR4. In the second row R2 and the fourth row R4, the first light emission area EA1 and the fourth light emission area EA4 may be alternately arranged or provided along the fourth direction DR4. In the first column C1 and the third column C3, the second light emission area EA2 and the fourth light emission area EA4 may be alternately arranged or provided along the fifth direction DR5. In the second column C2 and the fourth column C4, the first light emission area EA1 and the third light emission area EA3 may be alternately arranged or provided along the fourth direction DR4.

In one or more embodiments, the plurality of light emission areas EA1, EA2, EA3, and EA4 may be along the first direction DR1 or the second direction DR2. The first light emission area EA1 and the second light emission area EA2 may be alternately arranged or provided along the first direction DR1 and the second direction DR2. The third light emission area EA3 and the fourth light emission area EA4 may be alternately arranged or provided along the first direction DR1 and the second direction DR2.

The first light emission area EA1, the second light emission area EA2, the third light emission area EA3, and the fourth light emission area EA4 may be defined by a plurality of openings OPE1, OPE2, OPE3, and OPE4 in the pixel defining layer (‘PDL’ of FIG. 10) of the light emitting element layer EML, which will be described in more detail later. For example, the first light emission area EA1 may be defined by the first opening OPE1 of the pixel defining layer, the second light emission area EA2 may be defined by the second opening OPE2 of the pixel defining layer, the third light emission area EA3 may be defined by the third opening OPE3 of the pixel defining layer, and the fourth light emission area EA4 may be defined by the fourth opening OPE4 of the pixel defining layer.

In one or more embodiments, the first light emission area EA1, the second light emission area EA2, the third light emission area EA3, and the fourth light emission area EA4 may have different areas or sizes. In one or more embodiments of FIG. 8, a size of the second light emission area EA2 may be larger than sizes of the first light emission area EA1, the third light emission area EA3, and the fourth light emission area EA4, and the size of the first light emission area EA1 may be larger than the sizes of the third light emission area EA3 and the fourth light emission area EA4. The sizes of the light emission areas EA1, EA2, EA3, and EA4 may vary depending on sizes of the openings OPE1, OPE2, OPE3, and OPE4 in the pixel defining layer. The intensity of light emitted from the corresponding light emission areas EA1, EA2, EA3, and EA4 may vary depending on the sizes of the light emission areas EA1, EA2, EA3, and EA4, and a color of a screen displayed on the display device 10 or the electronic device 1 may be controlled or selected by adjusting the sizes of the light emission areas EA1, EA2, EA3, and EA4. In one or more embodiments of FIG. 8, the size of the second light emission area EA2 may be the largest, but embodiments of the present disclosure are not limited thereto. The sizes of the light emission areas EA1, EA2, EA3, and EA4 may be freely adjusted depending on the color of the screen desired or required by the display device 10 and the electronic device 1. In one or more embodiments, the sizes of the light emission areas EA1, EA2, EA3 and EA4 may be related to light efficiency, lifespan of a light emitting element ED, and/or the like, and may be in a trade-off relation with reflection by external light. The sizes of the light emission areas EA1, EA2, EA3 and EA4 may be adjusted in consideration of the above matters.

In one or more embodiments, the plurality of openings OPE1, OPE2, OPE3, and OPE4 and a plurality of light output portions OPT1, OPT2, OPT3, and OPT4 are illustrated and described in a circular shape (e.g., a substantially circular shape) by way of example, but embodiments of the present disclosure are not limited thereto, and may be applied to one or more suitable shapes, such as an oval shape (e.g., a substantially oval shape) or a polygonal structure (e.g., a substantially polygonal structure) with a curved edge.

Each of the plurality of pixels PX1, PX2, and PX3 may include the first light emission area EA1, the second light emission area EA2, the third light emission area EA3, and the fourth light emission area EA4 to be adjacent to one another, thereby expressing a white gray scale, but embodiments of the present disclosure are not limited thereto. One or more suitable modifications may be made in combination of the light emission areas EA1, EA2, EA3, and EA4 constituting one pixel group depending on the arrangement of the light emission areas EA1, EA2, EA3, and EA4 and the color of light emitted therefrom.

The non-light emission area NEA may be an area other than the light emission areas EA1, EA2, EA3, and EA4. The non-light emission area NEA may be between the light emission areas EA1, EA2, EA3, and EA4. The non-light emission area NEA may overlap the pixel defining layer. For example, the non-light emission area NEA may be substantially the same as an area of the pixel defining layer.

The display device 10 may include a plurality of color filters CF1, CF2, CF3, and CF4 on the light emission areas EA1, EA2, EA3, and EA4. The plurality of color filters CF1, CF2, CF3, and CF4 may be to correspond to the light emission areas EA1, EA2, EA3, and EA4. For example, the color filters CF1, CF2, CF3, and CF4 may be to overlap the light emission areas EA1, EA2, EA3, and EA4 or the openings OPE1, OPE2, OPE3, and OPT4 or the plurality of light output portions OPT1, OPT2, OPT3, and OPT4. The plurality of light output portions OPT1, OPT2, OPT3, and OPT4 may be partitioned by a light blocking pattern (‘BM’ of FIG. 10), may be to overlap the openings OPE1, OPE2, OPE3, and OPE4, and may form or provide a light output area through which light emitted from the light emission areas EA1, EA2, EA3, and EA4 is outputted. The color filters CF1, CF2, CF3, and CF4 may have an area larger than an area of each of the light output portions OPT1, OPT2, OPT3, and OPT4 and the openings OPE1, OPE2, OPE3, and OPE4, and the color filters CF1, CF2, CF3, and CF4 may completely (e.g., substantially completely) cover the light output area formed or provided by the light output portions OPT1, OPT2, OPT3, and OPT4.

The color filters CF1, CF2, CF3, and CF4 may be to correspond to different light emission areas EA1, EA2, EA3, and EA4, respectively. The color filters CF1, CF2, CF3, and CF4 may include a first color filter CF1, a second color filter CF2, a third color filter CF3, and a fourth color filter CF4. The color filters CF1, CF2, CF3, and CF4 may include a colorant, such as a dye and/or a pigment, which are to absorb light of different wavelength bands other than light of a set or specific wavelength band and may be to correspond to the colors of light emitted from the light emission areas EA1, EA2, EA3, and EA4.

For example, the first color filter CF1 may be a red color filter arranged or provided to overlap the first light emission area LA1 and transmit only the first light of the red color. The second color filter CF2 may be a blue color filter arranged or provided to overlap the second light emission area LA2 and transmit only the second light of the blue color. The third color filter CF3 may be to overlap the third light emission area EA3, and the fourth color filter CF4 may be to overlap the fourth light emission area LA4. The third color filter CF3 and the fourth color filter CF4 may be green color filters that are to transmit only the third light of the green color.

The first color filter CF1 may be to overlap the first light emission area EA1 but may be not to overlap the second light emission area EA2, the third light emission area EA3, and the fourth light emission area EA4. The second color filter CF2 may be to overlap the second light emission area EA2 but may be not to overlap the first light emission area EA1, the third light emission area EA3, and the fourth light emission area EA4. The third color filter CF3 may be to overlap the third light emission area EA3 but may be not to overlap the first light emission area EA1, the second light emission area EA2, and the fourth light emission area EA4. The fourth color filter CF4 may be to overlap the fourth light emission area EA4 but may be not to overlap the first light emission area EA1, the second light emission area EA2, and the third light emission area EA3.

The display device 10 may be to control or select a color of reflective light due to external light by adjusting arrangement, shape, and area of the color filters CF1, CF2, CF3, and CF4 on a plan view.

A touch electrode SEN may be between the light emission areas EA1, EA2, EA3, and EA4. The touch electrode SEN may be to be extended in the fourth direction DR4 and the fifth direction DR5 and may be spaced and/or apart (e.g., spaced apart or separated) from the light emission areas EA1, EA2, EA3, and EA4 by not overlapping them. The touch electrode SEN may be to overlap a pixel defining layer (‘PDL’ of FIG. 10) that includes the openings OPE1, OPE2, OPE3, and OPE4, and a light blocking layer (‘BM’ of FIG. 10′) that includes a plurality of light output portions OPT1, OPT2, OPT3, and OPT4 that will be described in more detail later. Although FIG. 8 briefly illustrates the touch electrode SEN, the touch electrode SEN may be any one selected from the touch driving electrode TE and the sensing electrode RE of FIG. 7.

FIG. 10 is a cross-sectional view taken along the line X1-X1′ of FIG. 9.

Referring to FIG. 10 in connection with FIGS. 8 and 9, the display panel 100 of the display device 10 according to one or more embodiments may include a substrate SUB, a display layer DU, a touch sensing layer TSU, a color filter layer CFL, and an overcoat layer OC. The display layer DU may include a thin film transistor layer TFTL, a light emitting element layer EML, and an encapsulation layer TFEL.

The substrate SUB may be a base substrate or a base member. The substrate SUB may be a flexible substrate capable of being subjected to bending, folding, rolling and/or the like. For example, the substrate SUB may contain a polymer resin, such as polyimide (PI), but embodiments of the present disclosure are not limited thereto. In one or more embodiments, the substrate SUB may contain a glass material and/or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be on the substrate SUB. The first buffer layer BF1 may include an inorganic layer capable of preventing permeation (or reducing a degree or occurrence of permeation) of the air and/or moisture. For example, the first buffer layer BF1 may include a plurality of inorganic layers that are alternately stacked.

The lower metal layer BML may be on the first buffer layer BF1. For example, the lower metal layer BML may be of a single layer or multi-layer made of any one of molybdenum (Mo), aluminum (AI), chromium (Cr), gold (Au), titanium (Ti), nickel (Ni), neodymium (Nd), tantalum (Ta), copper (Cu), or a (e.g., any suitable) alloy thereof.

The second buffer layer BF2 may cover the first buffer layer BF1 and the lower metal layer BML. The second buffer layer BF2 may include an inorganic layer capable of preventing permeation (or reducing a degree or occurrence of permeation) of the air and/or moisture. For example, the second buffer layer BF2 may include a plurality of inorganic layers alternately stacked.

The thin film transistor TFT may be on the second buffer layer BF2 and may constitute a pixel circuit of each of the plurality of pixels. For example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be on the second buffer layer BF2. The semiconductor layer ACT may overlap the lower metal layer BML and the gate electrode GE in the thickness direction and may be insulated from the gate electrode GE by the gate insulating layer GI. A material of a portion of the semiconductor layer ACT may be conductorized (or may become electrically conductive) to form or provide the source electrode SE and the drain electrode DE.

The gate electrode GE may be on the gate insulating layer GI. The gate electrode GE may overlap the semiconductor layer ACT with the gate insulating layer GI therebetween.

The gate insulating layer GI may be on the semiconductor layer ACT. For example, the gate insulating layer GI may cover the semiconductor layer ACT and the second buffer layer BF2 and may insulate the semiconductor layer ACT from the gate electrode GE. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and a contact hole of the second interlayer insulating layer ILD2.

The capacitor electrode CPE may be on the first interlayer insulating layer ILD1. The capacitor electrode CPE may overlap the gate electrode GE in the thickness direction. The capacitor electrode CPE and the gate electrode GE may form or provide capacitance.

The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be on the second interlayer insulating layer ILD2. The first connection electrode CNE1 may electrically connect the drain electrode DE of the thin film transistor TFT with (or to) the second connection electrode CNE2. The first connection electrode CNE1 may be inserted into the contact holes in the second interlayer insulating layer ILD2, the first interlayer insulating layer ILD1, and the gate insulating layer GI to contact the drain electrode DE of the thin film transistor TFT.

The first passivation layer PAS1 may cover the first connection electrode CNE1 and the second interlayer insulating layer ILD2. The first passivation layer PAS1 may be to protect the thin film transistor TFT. The first passivation layer PAS1 may include a contact hole through which the second connection electrode CNE2 passes.

The second connection electrode CNE2 may be on the first passivation layer PAS1. The second connection electrode CNE2 may electrically connect the first connection electrode CNE1 to a pixel electrode AE of the light emitting element ED. The second connection electrode CNE2 may be inserted into the contact hole in the first passivation layer PAS1 to contact the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED passes.

The light emitting element layer EML may be on the thin film transistor layer TFTL. The light emitting element layer EML may include a light emitting element ED and a pixel defining layer PDL. The light emitting element ED may include a pixel electrode AE, a light emitting layer EL, and a common electrode CO.

The pixel electrode AE may be on the second passivation layer PAS2. The pixel electrode AE may be to overlap any one selected from among the openings OPE1, OPE2, and OPE3 of the pixel defining layer PDL. The pixel electrode AE may be electrically connected to the drain electrode DE of the thin film transistor TFT through the first and second connection electrodes CNE1 and CNE2.

The light emitting layer EL may be on the pixel electrode AE. For example, the light emitting layer EL may be an organic light emitting layer made of an organic material, but embodiments of the present disclosure are not limited thereto. If (e.g., when) the light emitting layer EL corresponds to the organic light emitting layer, the thin film transistor TFT may apply a set or predetermined voltage to the pixel electrode AE of the light emitting element ED. If (e.g., when) the common electrode CO of the light emitting element ED receives a common voltage or a cathode voltage, holes and electrons may move to the light emitting layer EL through a hole transporting layer and an electron transporting layer, respectively, and may be combined with each other in the light emitting layer EL to emit light.

The common electrode CO may be on the light emitting layer EL. For example, the common electrode CO may be implemented in the form of an electrode that is not divided for each of the plurality of pixels and is common to all of the pixels. The common electrode CO may be on the light emitting layer EL in the light emission areas EA1, EA2, and EA3 and may be on the pixel defining layer PDL in an area other than the first light emission area EA1, the second light emission area EA2, and the third light emission area EA3.

The common electrode CO may be to receive a common voltage or a low potential voltage. If (e.g., when) the pixel electrode AE receives a voltage that corresponds to the data voltage and the common electrode CO receives the low potential voltage, a potential difference may be formed or provided between the pixel electrode AE and the common electrode CO, whereby the light emitting layer EL may be to emit light.

The pixel defining layer PDL may include a plurality of openings OPE1, OPE2, and OPE3, and thus may be on a portion of the pixel electrode AE and the second passivation layer PAS2. The pixel defining layer PDL may include a first opening OPE1, a second opening OPE2, and a third opening OPE3, and each of the openings OPE1, OPE2, and OPE3 may expose a portion of the pixel electrode AE. In one or more embodiments, the openings OPE1, OPE2, and OPE3 of the pixel defining layer PDL may define the first light emission area EA1, the second light emission area EA2, and the third light emission area EA3, respectively, and may have different areas or sizes. The pixel defining layer PDL may separate and insulate the pixel electrode AE of each of the plurality of light emitting elements ED from another one.

The pixel defining layer PDL may include a light absorbing material to prevent light reflection (or to reduce a degree or occurrence of light reflection). For example, the pixel defining layer PDL may include a polyimide (PI)-based binder and a pigment in which red, green, and blue are mixed. In one or more embodiments, the pixel defining layer PDL may include a cardo-based binder resin, and/or a (e.g., any suitable) mixture of a lactam black pigment and a blue pigment. In one or more embodiments, the pixel defining layer PDL may include carbon black.

A spacer SPC may be on the pixel defining layer PDL. The spacer SPC may act or serve to prevent damage (or to reduce a degree or occurrence of damage) to lower layers due to contact of a mask during a deposition process of the light emitting layer EL. The spacer SPC may be directly on the pixel defining layer PDL and may be to overlap the non-light emission area NEA. The spacer SPC may include an organic material and may be to have a thick thickness of 1 μm or more.

The encapsulation layer TFEL may be on the common electrode CO to cover the plurality of light emitting elements ED. The encapsulation layer TFEL may include at least one inorganic layer to prevent oxygen and/or moisture from being permeated (or to reduce a degree or occurrence of permeation of oxygen and/or moisture) into the light emitting element layer EML. The encapsulation layer TFEL may include at least one organic layer to protect the light emitting element layer EML from particles, such as dust.

The encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 therebetween may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon nitride, and/or silicon oxynitride.

The second encapsulation layer TFE2 may include an organic insulating material. For example, the organic insulating material may include an acrylic resin, an epoxy resin, polyimide, and/or polyethylene. The second encapsulation layer TFE2 may be formed or provided by curing a monomer and/or coating a polymer.

The touch sensing layer TSU may be on the encapsulation layer TFEL. The touch sensing layer TSU may include a touch insulating layer TNS, a driving electrode TE, and a bridge electrode CE. In one or more embodiments, the touch sensing layer TSU may further include the sensing electrode RE as illustrated in FIG. 7.

The driving electrode TE may be on the third encapsulation layer TFE3. The driving electrode TE may be of a single layer made of molybdenum (Mo), titanium (Ti), copper (Cu), aluminum (AI), and/or indium tin oxide (ITO) or may be of a stacked structure (Ti/Al/Ti) of aluminum and titanium, a stacked structure (ITO/AI/ITO) of aluminum and ITO, APC (Aluminum-Polymer Composite) alloy, and a stacked structure (ITO/AI/ITO) of APC alloy and ITO. In the present content and unless defined otherwise, the term “APC alloy” refers to a composite material that includes Al as a primary component, combined with other elements to enhance its properties. The specific components of an APC alloy may vary, and may include Al, a polymer, Cu, Ti, ITO, and/or the like. The driving electrode TE may be arranged or provided not to overlap the first light emission area EA1, the second light emission area EA2, and the third light emission area EA3.

The touch insulating layer TNS may be on the driving electrode TE and the third encapsulation layer TFE3. The touch insulating layer TNS may include an organic layer and/or an inorganic layer. For example, the touch insulating layer TNS may include an organic layer, such as an acrylic resin, an epoxy-based resin, polyimide, and/or polyethylene or may include an inorganic layer, such as silicon nitride, silicon oxide, and/or silicon oxynitride.

The bridge electrode CE may be on the touch insulating layer TNS and may be connected to the driving electrode TE through a contact hole that passes through the touch insulating layer TNS. The bridge electrode CE may be made of a material exemplified in the driving electrode TE.

The driving electrode TE and the bridge electrode CE of the touch sensing layer TSU may be to overlap a plurality of protrusions PRJ and a light blocking pattern BM. Therefore, the driving electrode TE and the bridge electrode CE may be covered by the light blocking pattern BM, whereby the driving electrode TE and the bridge electrode CE may be prevented from being visually recognized from the outside (a degree to or occurrence of which the driving electrode TE and the bridge electrode CE are visually recognizable from the outside may be reduced).

A color filter layer CFL may be on the touch sensing layer TSU. The color filter layer CFL may be a reflective control layer that controls or select reflection of external light. The color filter layer CFL may include a plurality of color filters CF1, CF2, and CF3 and a light blocking pattern BM. Each of the color filters may be to selectively transmit light of a set or specific wavelength and to block or absorb light of another wavelength. The color filter layer CFL may be to absorb a portion of the light introduced from the outside of the display device 10 to reduce the reflective light due to the external light. Therefore, the color filter layer CFL may prevent color distortion (or reduce a degree or occurrence of color distortion) due to reflection of the external light.

The light blocking pattern BM may be on the touch insulating layer TNS of the touch sensing layer TSU. The light blocking pattern BM may be to cover a conductive line of the driving electrode TE, and may partition the plurality of light output portions OPT1, OPT2, and OPT3 that are to overlap the first light emission area EA1, the second light emission area EA2, and the third light emission area EA3. For example, the first light output portion OPT1 may be to overlap the first light emission area EA1 or the first opening OPE1. The second light output portion OPT2 may be to overlap the second light emission area EA2 or the second opening OPE2, and the third light output portion OPT3 may be to overlap the third light emission area EA3 or the third opening OPE3. In one or more embodiments, the fourth light output portion OPT4 may be to overlap the fourth light emission area EA4 or the fourth opening OPE4.

An area or size of each of the light output portions OPT1, OPT2, OPT3, and OPT4 may be larger than an area or size of each of the openings OPE1, OPE2, OPE3, and OPE4 of the pixel defining layer PDL. As the light output portions OPT1, OPT2, OPT3, and OPT4 of the light blocking pattern BM are formed or provided to be larger than the openings OPE1, OPE2, OPE3, and OPE4 of the pixel defining layer PDL, light emitted from the light emission areas EA1, EA2, EA3, and EA4 may be visually recognized by a user not only on a front surface of the display device 10 but also on a side of the display device 10.

The light blocking pattern BM may include a light absorbing material. For example, the light blocking pattern BM may include an inorganic black pigment and/or an organic black pigment. The inorganic black pigment may be carbon black, and the organic black pigment may include at least one of lactam black, perylene black, or aniline black, but embodiments of the present disclosure are not limited thereto. The light blocking pattern BM may improve or enhance a color reproduction rate of the display device 10 by preventing visible light from being permeated and from mixing colors (or by reducing a degree to or occurrence of which visible light is permeated or mixes colors) between the first light emission area EA1, the second light emission area EA2, the third light emission area EA3, and the fourth light emission area EA4.

In one or more embodiments, the light blocking pattern BM may be defined as an area where the plurality of color filters CF1, CF2, and CF3 overlap one another. For example, an area where the first color filter CF1, the second color filter CF2, and the third color filter CF3, which will be described in more detail later, overlap one another in the third direction DR3, may be defined as the light blocking pattern BM. In one or more embodiments, each of the first color filter CF1, the second color filter CF2, and the third color filter CF3 may finally be to block light by substantially blocking the other light except red light, green light, and blue light.

The plurality of color filters CF1, CF2, and CF3 of the color filter layer CFL may be on the light blocking pattern BM and the touch insulating layer TNS. The plurality of color filters CF1, CF2, and CF3 may include a first color filter CF1, a second color filter CF2, and a third color filter CF3.

The first color filter CF1 may be to overlap the first output portion OPT1 and the first light emission area EA1, and a portion of the first color filter CF1 may be to overlap the non-light emission area NEA. The first color filter CF1 may be to selectively transmit light of the first color (e.g., red) and to block or absorb light of the second color (e.g., blue) and light of the third color (e.g., green). For example, the first color filter CF1 may be a red color filter and may include a red colorant, but embodiments of the present disclosure are not limited thereto.

The second color filter CF2 may be to overlap the second light output portion OPT2 and the second light emission area EA2, and a portion of the second color filter CF2 may be to overlap the non-light emission area NEA. The second color filter CF2 may be to selectively transmit light of the second color (e.g., blue) and may be to block or absorb light of the third color (e.g., green) and light of the first color (e.g., red). For example, the second color filter CF2 may be a blue color filter and may include a blue colorant, but embodiments of the present disclosure are not limited thereto.

The third color filter CF3 may be to overlap the third light output portion OPT3 and the third light emission area EA3, and a portion of the third color filter CF3 may be to overlap the non-light emission area NEA. The third color filter CF3 may be to selectively transmit light of the third color (e.g., green) and to block or absorb light of the first color (e.g., red) and light of the second color (e.g., blue). For example, the third color filter CF3 may be a green color filter and may include a green colorant, but embodiments of the present disclosure are not limited thereto. In one or more embodiments, the fourth color filter CF4 may be a green color filter in substantially the same manner as the third color filter CF3 and may be to overlap the fourth light output portion OPT4 and the fourth light emission area EA4.

The overcoat layer OC may be on the color filter layer CFL. The overcoat layer OC may cover the color filter layer CFL to planarize a step (e.g., act or task) difference therebelow. The overcoat layer OC may be a colorless (e.g., substantially colorless) light-transmitting layer that does not have a color of a visible light band. For example, the overcoat layer OC may include a colorless (e.g., substantially colorless) light-transmitting organic material, such as an acrylic resin and/or polyimide.

In one or more embodiments, the overcoat layer OC may further include a dye capable of selectively absorbing light of a set or specific wavelength band. The overcoat layer OC may reduce reflectance of external light (or a degree or occurrence of reflectance of external light) by absorbing light of a partial wavelength band of light incident from the outside.

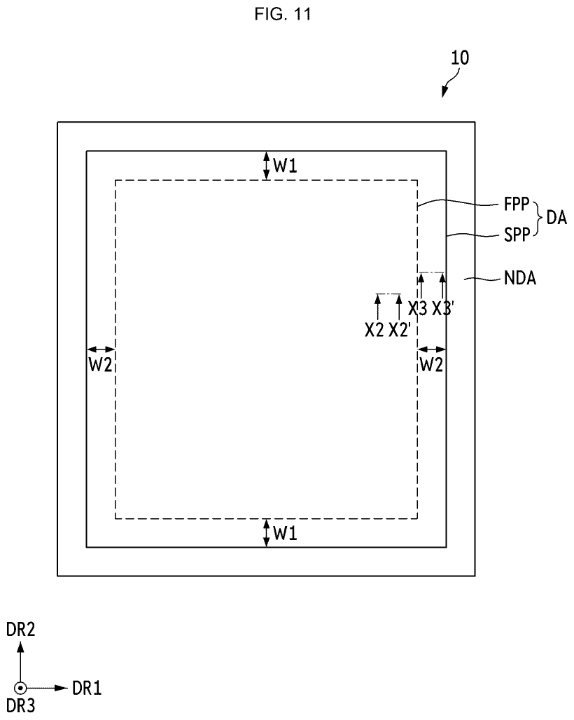

FIG. 11 is a schematic plan view illustrating a display device according to one or more embodiments.

Referring to FIG. 11, the display device 10 may include a display area DA and a non-display area NDA around (e.g., surrounding) the display area DA as described in one or more embodiments. The display area DA may include a first area FPP that corresponds to a central portion of the display area DA and a second area SPP around (e.g., surrounding) the first area FPP.

The first area FPP may be an area that corresponds to the central portion of the display area DA and may occupy most of the display area DA. The second area SPP may be an area that corresponds to the edge of the display area DA and may be arranged or provided to be around (e.g., surround) the first area FPP. A boundary between the first area FPP and the second area SPP may be in a shape substantially similar to the boundary between the display area DA and the non-display area NDA.

The second area SPP may have a set or predetermined width. A first width W1 of the second area SPP, which is measured in the second direction DR2, may be about 1% to about 8% of a width of the display area DA, which is measured in the second direction DR2. In one or more embodiments, a second width W2 of the second area SPP, which is measured in the first direction DR1, may be about 1% to about 8% of a width of the display area DA, which is measured in the first direction DR1.

The display device 10 may include a color filter layer CFL, as illustrated in FIG. 10. Each of the color filters CF1, CF2, and CF3 in the color filter layer CFL may be formed or provide by an inkjet printing method. Due to characteristics of a solution process, an ink for a color filter may be uniformly (e.g., substantially uniformly) coated in the first area FPP of the display area DA, but may be coated to be gradually thinner in the second area SPP. For example, because the color filters CF1, CF2, and CF3 in the second area SPP are relatively thin, a luminance difference between the first area FPP and the second area SPP may occur in the display area DA.

Hereinafter, in the present disclosure, a display device 10 capable of resolving a luminance difference between the first area FPP and the second area SPP of the display area DA will be described.

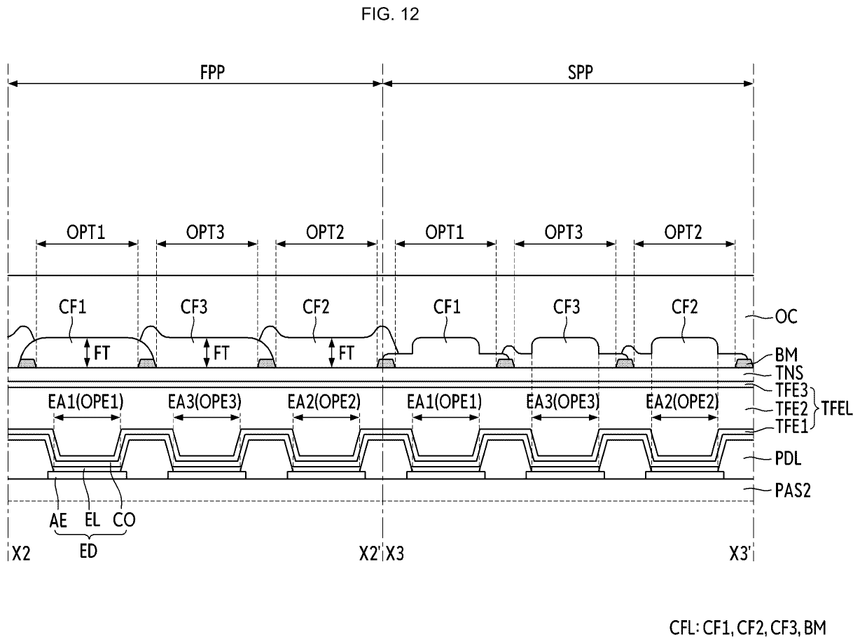

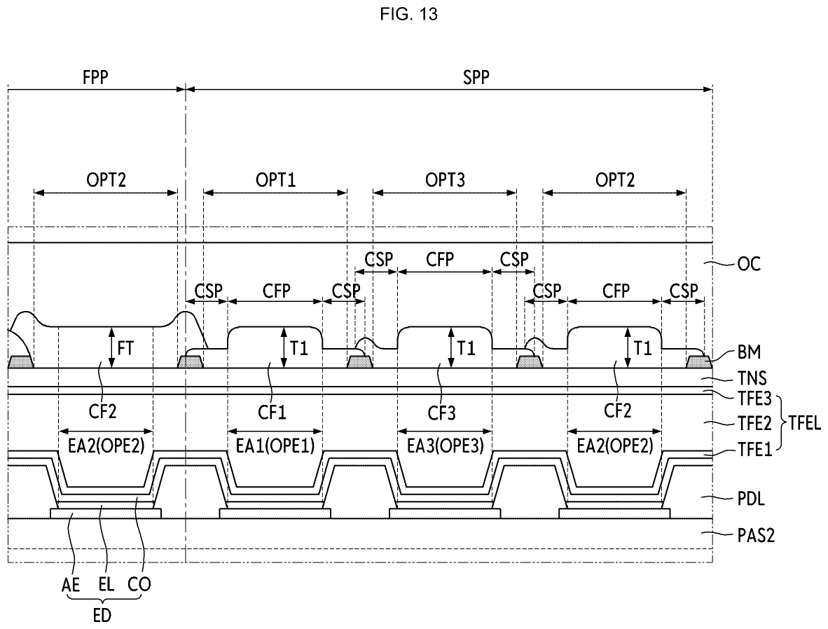

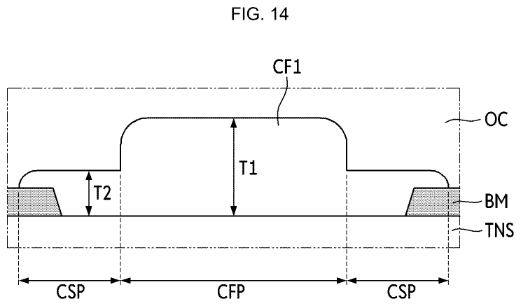

FIG. 12 is a cross-sectional view taken along the lines X2-X2′ and X3-X3′ of FIG. 1. FIG. 13 is a view illustrating a second light emission area of a first area and a first light emission area, a second light emission area, and a third light emission area of a second area in a display area of FIG. 12. FIG. 14 is an enlarged view illustrating a first color filter of a second area of FIG. 13.

Referring to FIGS. 12 to 14, the display area DA may include light emission areas EA1, EA2, and EA3 in each of the first area FPP and the second area SPP. Each of the light emission areas EA1, EA2, and EA3 may be partitioned by each of the openings OPE1, OPE2, and OPE3 of the pixel defining layer PDL, and the light emitting elements ED in each of the light emission areas EA1, EA2, and EA3 may be to emit light. The thin film encapsulation layer TFEL may be on the light emitting elements ED, and the touch insulating layer TNS may be on the thin film encapsulation layer TFEL.

The color filter layer CFL may be on the touch insulating layer TNS. The color filter layer CFL may include a light blocking pattern BM that does not overlap each of the light emission areas EA1, EA2, and EA3 and color filters CF1, CF2, and CF3 that overlap the light emission areas EA1, EA2, and EA3, respectively. The light blocking pattern BM may partition the light output portions OPT1, OPT2, and OPT3 that overlap the light emission areas EA1, EA2, and EA3, respectively. The color filters CF1, CF2, and CF3 may overlap the light output portions OPT1, OPT2, and OPT3, respectively.

The color filters CF1, CF2, and CF3 in the first area FPP may be with a set or predetermined thickness. Each of the color filters CF1, CF2, and CF3 may have a set or predetermined thickness in an area that overlaps each of the light emission areas EA1, EA2, and EA3. For example, each of the first color filter CF1 that overlaps the first light emission area EA1, the second color filter CF2 that overlaps the second light emission area EA2, and the third color filter CF3 that overlaps the third light emission area EA3 may have a set or predetermined thickness FT. The thicknesses FT of the first color filter CF1, the second color filter CF2, and the third color filter CF3 may be substantially similar to one another and may be substantially the same as one another.

The color filters CF1, CF2, and CF3 in the second area SPP may be arranged or provided with a set or predetermined thickness. Each of the color filters CF1, CF2, and CF3 may have a set or predetermined thickness in an area that overlaps each of the light emission areas EA1, EA2, and EA3.

In more detail, each of the color filters CF1, CF2, and CF3 in the second area SPP may include a first portion CFP and a second portion CSP. The first portion CFP may be a portion protruded from each of the color filters CF1, CF2, and CF3 in the thickness direction. For example, the first portion CFP may be more protruded than the second portion CSP in the thickness direction.

The first portion CFP may overlap each of the light emission areas EA1, EA2, and EA3, and the second portion CSP may not overlap each of the light emission areas EA1, EA2, and EA3. For example, the first portion CF of the first color filter CF1 may overlap the first light emission area EA1, and the second portion CSP of the first color filter CF1 may not overlap the first light emission area EA1. The first portion CFP of the second color filter CF2 may overlap the second light emission area EA2, and the second portion CSP of the second color filter CF2 may not overlap the second light emission area EA2. The first portion CFP of the third color filter CF3 may overlap the third light emission area EA3, and the second portion CSP of the third color filter CF3 may not overlap the third light emission area EA3. The first portion CFP of each of the color filters CF1, CF2, and CF3 may not overlap the pixel defining layer PDL and the light blocking pattern BM. The second portion CSP of each of the color filters CF1, CF2, and CF3 may overlap the pixel defining layer PDL and the light blocking pattern BM and may be arranged or provided to be around (e.g., surround) the first portion CFP on a plane.

The first portion CFP of each of the color filters CF1, CF2, and CF3 in the second area SPP may have a first thickness T1, and the second portion CSP thereof may have a second thickness T2. In one or more embodiments, the first thickness T1 and the second thickness T2 may refer to a distance from an upper surface of the touch insulating layer TNS to an upper surface of each of the color filters CF1, CF2, and CF3, which is measured in the third direction DR3. The first thicknesses T1 of the first portions CFP of the color filters CF1, CF2, and CF3 may be substantially the same as one another. For example, the first thickness T1 of the first portion CFP of the first color filter CF1 may be substantially the same as each of the first thickness T1 of the first portion CFP of the second color filter CF2 and the first thickness T1 of the first portion CFP of the third color filter CF3.

The first thickness T1 of the first portion CFP of each of the color filters CF1, CF2, and CF3 may be greater than the second thickness T2 of the second portion CSP. For example, the second thickness T2 of the second portion CSP of each of the color filters CF1, CF2, and CF3 may be smaller than the first thickness T1 of the first portion CFP. For example, the first thickness T1 of the first portion CFP of the first color filter CF1 may be greater than the second thickness T2 of the second portion CSP, and the first thickness T1 of the first portion CFP of the second color filter CF2 may be greater than the second thickness T2 of the second portion CSP, and the first thickness T1 of the first portion CFP of the third color filter CF3 may be greater than the second thickness T2 of the second portion CSP.

According to one or more embodiments, the first thickness T1 of the first portion CFP of each of the color filters CF1, CF2, and CF3 in the second area SPP may be substantially the same as the thickness FT of each of the color filters CF1, CF2, and CF3 in the first area FPP. The thickness FT of each of the color filters CF1, CF2, and CF3 in the first area FPP may be a thickness measured in the area that overlaps each of the light emission areas EA1, EA2, and EA3.

Light emitted from each of the light emission areas EA1, EA2, and EA3 in the second area SPP may be most visually recognized by the user through the first portion CFP of each of the color filters CF1, CF2, and CF3 that overlap the light emission areas EA1, EA2, and EA3. Therefore, luminance seen by the user may be greatly influenced by the first thickness T1 of the first portion CFP of each of the color filters CF1, CF2, and CF3. In the present disclosure, the first portion CFP of each of the color filters CF1, CF2, and CF3 in the second area SPP may be formed or provided to have the first thickness T1 substantially the same as the thickness FT of each of the color filters CF1, CF2, and CF3 in the first area FPP, so that the luminance difference between the first area FPP and the second area SPP of the display device 10 may be substantially resolved.

For example, a display device 10 may be designed to resolve luminance differences between the first area FPP and the second area SPP of the display area DA. The display area may include light emission areas EA1, EA2, and EA3 in both (e.g., simultaneously) the first area and the second area, partitioned by openings in the pixel defining layer PDL. Light emitting elements ED in these areas may emit light, which is encapsulated by a thin film encapsulation layer TFEL and covered by a touch insulating layer TNS. A color filter layer CFL on the touch insulating layer may include a light blocking pattern BM and color filters CF1, CF2, and CF3 that overlap the light emission areas.

The color filters in the first area FPP may have a set or predetermined thickness FT, which is substantially consistent across the filters. In the second area SPP, the color filters may include a first portion CFP that overlaps the light emission areas and a second portion CSP that does not. The first portion may have a greater thickness (T1) than the second portion (T2), and this thickness (T1) may be substantially similar to the thickness (FT) of the color filters in the first area. This design may ensure that the luminance seen by the user is substantially consistent across the display, effectively or suitably resolving any luminance differences between the central and edge areas of the display device.

Hereinafter, a method for fabricating the display device 10 as described in one or more embodiments will be described with reference to other drawings.

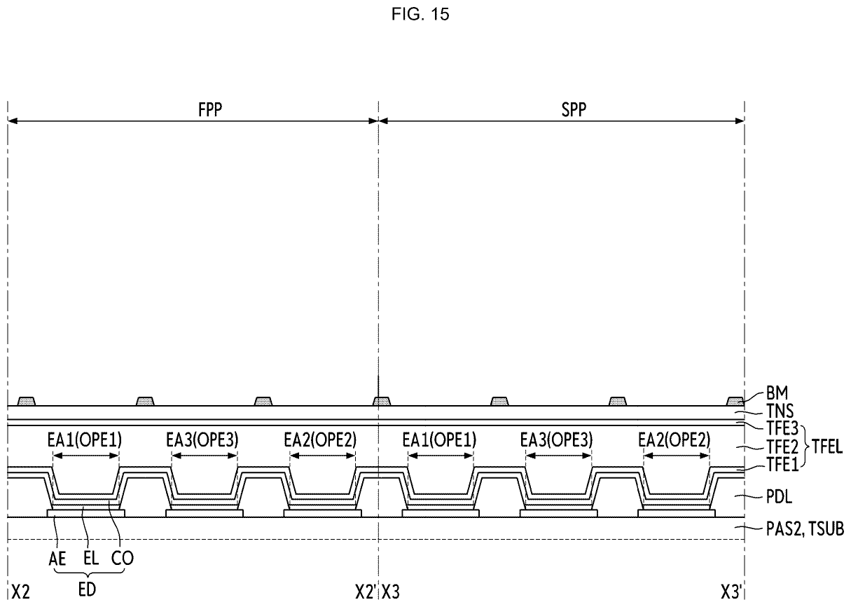

FIGS. 15 to 21 each is a cross-sectional view for each process of a display device according to one or more embodiments. FIGS. 15 to 21 each illustrates portions that correspond to FIG. 12 as described in one or more embodiments, and a process of fabricating a substrate SUB, a thin film transistor layer TFTL, a light emitting element layer EML, an encapsulation layer TFEL, and a touch sensing layer TSU will not be provided, and the description will be based on a process of fabricating a color filter layer CFL.

Referring to FIG. 15, the light emitting element layer EML, the encapsulation layer TFEL, and the touch sensing layer TSU may be sequentially formed or provided on a target substrate TSUB. The target substrate TSUB may be a substrate that has a thin film transistor layer thereon. For example, a pixel electrode AE may be on a second passivation layer PAS2 of the target substrate TSUB, and a pixel defining layer PDL may be to partition each of light emission areas EA1, EA2, and EA3.

Subsequently, a light emitting layer EL may be on the pixel electrode AE, and a common electrode CO may be on the light emitting layer EL and the pixel defining layer PDL, whereby a light emitting element EML including a light emitting element ED may be fabricated.

Next, a first encapsulation layer TFE1, a second encapsulation layer TFE2, and a third encapsulation layer TFE3 may be sequentially formed or provided on the light emitting element layer EML to form or provide a thin film encapsulation layer TFEL. A touch insulating layer TNS, a driving electrode, and a bridge electrode may be on the thin film encapsulation layer TFEL to form or provide the touch sensing layer TSU.

Subsequently, a light blocking pattern BM may be on the touch insulating layer TNS of the touch sensing layer TSU. The light blocking pattern BM may be formed or provided by forming or providing a light blocking material layer and patterning the light blocking material layer through a photo process.

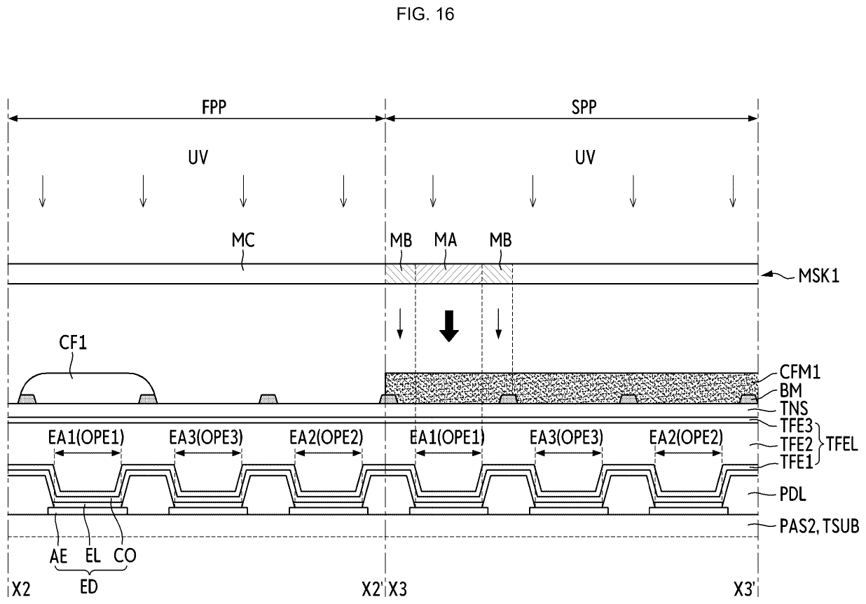

Next, referring to FIG. 16, a first color filter CF1 may be in an area that corresponds to the first light emission area EA1 of a first area FPP on the target substrate TSUB. The first color filter CF1 may be formed or provided by a color filter process that is generally available or generally used. For example, the first color filter CF1 may be formed or provided by coating a color material and through exposure and development.

Subsequently, a first color material layer CFM1 may be on a second area SPP of the target substrate SUB. The first color material layer CFM1 may be formed or provided by using an inkjet printing method, but embodiments of the present disclosure are not limited thereto, and may be formed or provided by a solution process, such as spin coating and/or slit coating.

Next, a first mask MSK1 may be aligned on the target substrate TSUB. The first mask MSK1 may be a halftone mask provided with a transmissive area MA, a semi-transmissive area MB, and a light blocking area MC. The transmissive area MA may be an area that is to transmit most of light that is irradiated, the semi-transmissive area MB may be an area that is to transmit only a portion of light that is irradiated, and the light blocking area MC may be an area that is to block light that is irradiated. The transmissive area MA may be aligned to overlap the first light emission area EA1 of the second area SPP.

Subsequently, an exposure process may be performed by irradiating UV light onto the first mask MSK1. In the exposure process, UV light may be irradiated to a partial area of the first color material layer CFM1 through the transmissive area MA of the first mask MSK1, UV light may be partially irradiated to another partial area of the first color material layer CFM1 through the semi-transmissive area MB, and UV light may not be irradiated to the first color material layer CFM1 through the light blocking area MB.

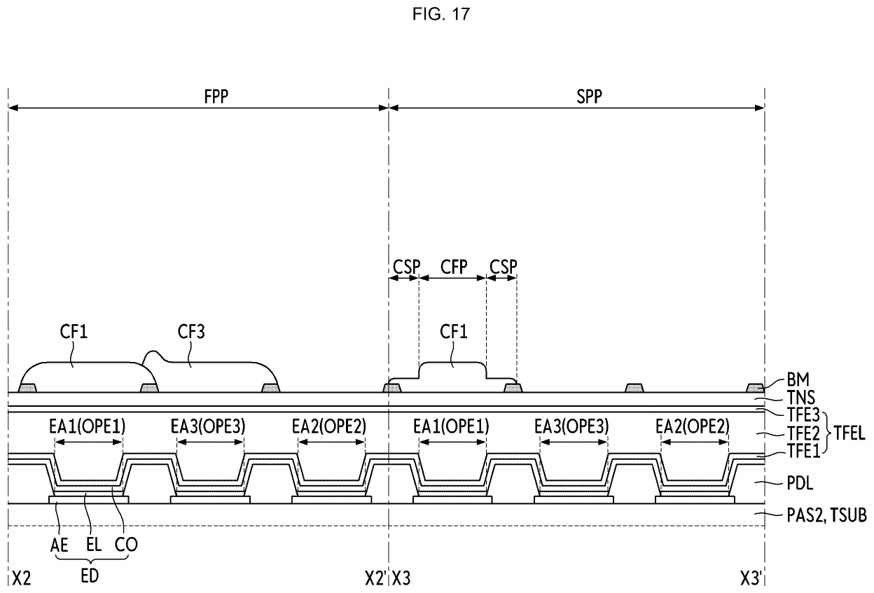

Next, referring to FIG. 17, the first color filter CF1 may be on the first light emission area EA1 of the second area SPP by developing the first color material layer CF1. In one or more embodiments, an area that corresponds to the transmissive area MA of the first mask MSK1 may not be removed by a developing solution but formed or provided as a first portion CFP of the first color filter CF1, an area that corresponds to the semi-transmissive area MB may be partially removed by the developing solution and thus formed or provided as a second portion CSP of the first color filter CF1, and an area that corresponds to the light blocking area MC may be fully (e.g., substantially fully) removed by the developing solution.

In one or more embodiments, because a color material is again coated onto the second area SPP after the first color filter CF1 of the first area FPP is formed or provided, a thickness of the first color material layer CFM1 coated in the second area SPP may be substantially the same as that of the first area FPP. Therefore, a thickness of the first portion CFP of the first color filter CF1 of the second area SPP may be substantially the same as that of the first color filter CF1 of the first area FPP.

Next, a third color filter CF3 may be formed or provided in an area that corresponds to the third light emission area EA3 of the first area FPP. Like the first color filter CF1 of the first area FPP, the third color filter CF3 of the first area FPP may be formed or provided by a color filter process that is generally available or generally used.

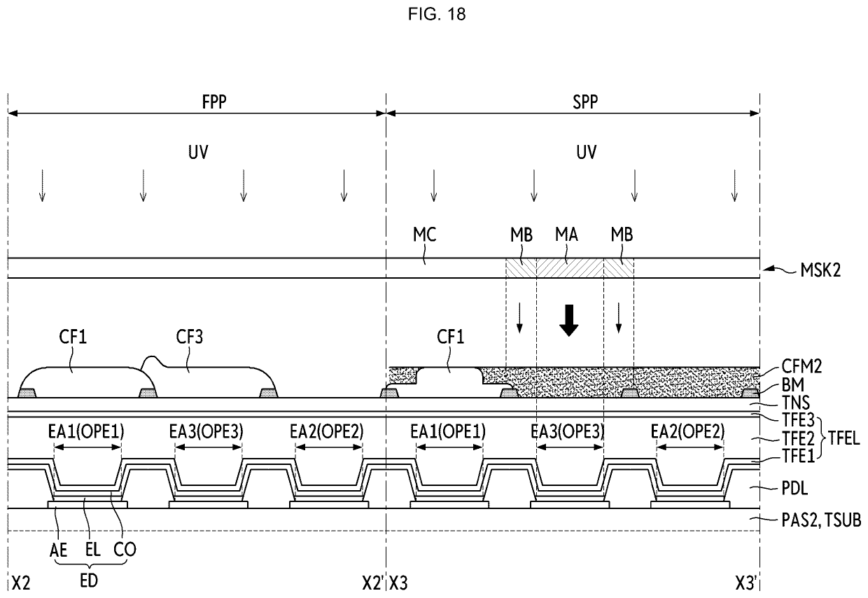

Subsequently, referring to FIG. 18, a second color material layer CFM2 may be formed or provided on the second area SPP of the target substrate SUB. The second color material layer CFM1 may be formed or provided by using an inkjet printing method, but embodiments of the present disclosure are not limited thereto, and may be formed or provided by a solution process, such as spin coating and/or slit coating.

Next, a second mask MSK2 may be aligned on the target substrate TSUB. Like the first mask MSK1, the second mask MSK2 may be a halftone mask provided with a transmissive area MA, a semi-transmissive area MB, and a light blocking area MC. The transmissive area MA may be aligned to overlap the third light emission area EA3 of the second area SPP.

Subsequently, an exposure process may be performed by irradiating UV light onto the second mask MSK2. In the exposure process, UV light may be irradiated to a partial area of the second color material layer CFM2 through the transmissive area MA of the second mask MSK2, UV light may be partially irradiated to another partial area of the second color material layer CFM2 through the semi-transmissive area MB, and UV light may not be irradiated to the second color material layer CFM2 through the light blocking area MB.

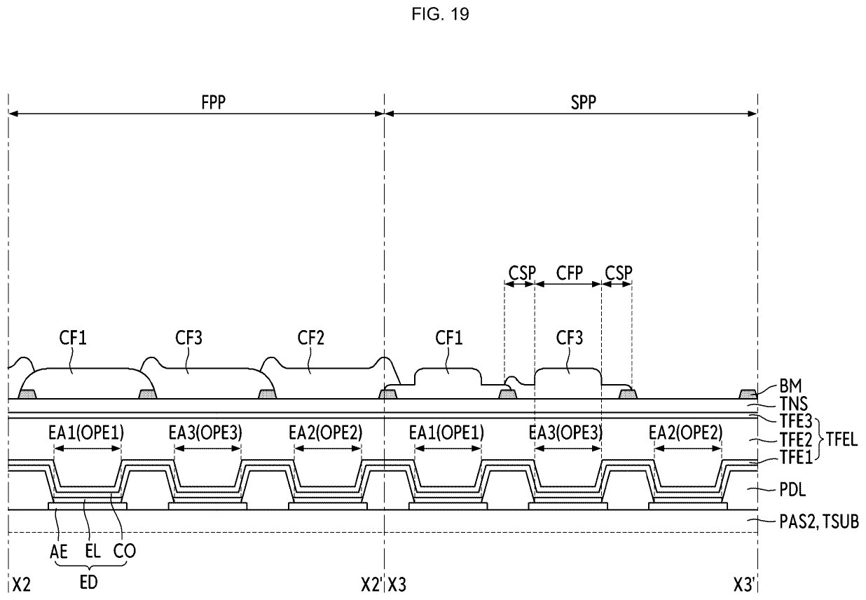

Next, referring to FIG. 19, the third color filter CF3 may be formed or provided on the third light emission area EA3 of the second area SPP by developing the second color material layer CFM2. In one or more embodiments, an area that corresponds to the transmissive area MA of the second mask MSK2 may not be removed by a developing solution but formed or provided as a first portion CFP of the third color filter CF3, an area that corresponds to the semi-transmissive area MB may be partially removed by the developing solution and thus formed or provided as a second portion CSP of the third color filter CF3, and an area that corresponds to the light blocking area MC may be fully (e.g., substantially fully) removed by the developing solution.

Next, a second color filter CF2 may be formed or provided in an area that corresponds to the second light emission area EA2 of the first area FPP. Like the first color filter CF1 and the third color filter CF3 of the first area FPP, the second color filter CF2 of the first area FPP may be formed or provided by a color filter process that is generally available or generally used.

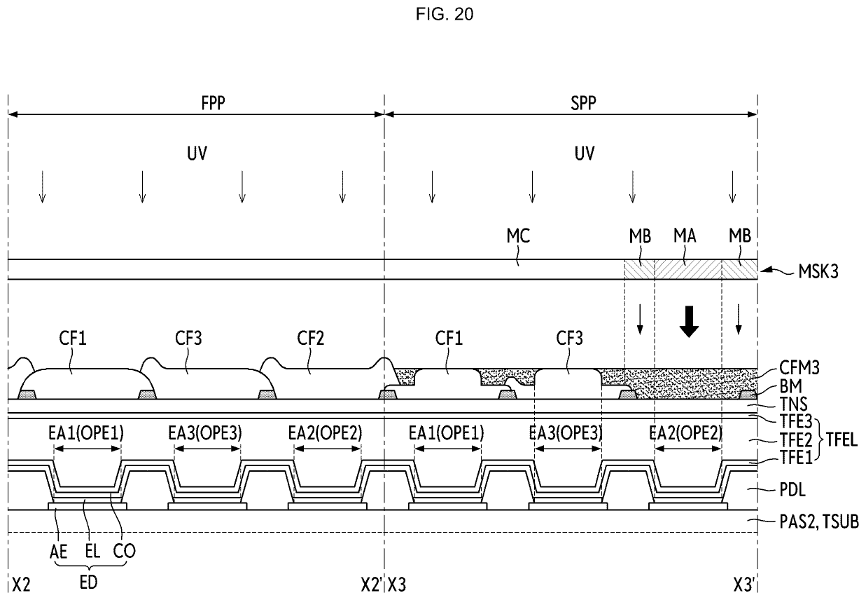

Subsequently, referring to FIG. 20, a third color material layer CFM3 may be formed or provided on the second area SPP of the target substrate SUB. The third color material layer CFM3 may be formed or provided by using an inkjet printing method, but embodiments of the present disclosure are not limited thereto, and may be formed or provided by a solution process, such as spin coating and/or slit coating.

Next, a third mask MSK3 may be aligned on the target substrate TSUB. Like the first mask MSK1, the third mask MSK3 may be a halftone mask provided with a transmissive area MA, a semi-transmissive area MB, and a light blocking area MC. The transmissive area MA may be aligned to overlap the second light emission area EA2 of the second area SPP.

Subsequently, an exposure process may be performed by irradiating UV light onto the third mask MSK3. In the exposure process, UV light may be irradiated to a partial area of the third color material layer CFM3 through the transmissive area MA of the third mask MSK3, UV light may be partially irradiated to another partial area of the third color material layer CFM3 through the transmissive area MB, and UV light may not be irradiated to the third color material layer CFM3 through the light blocking area MB.

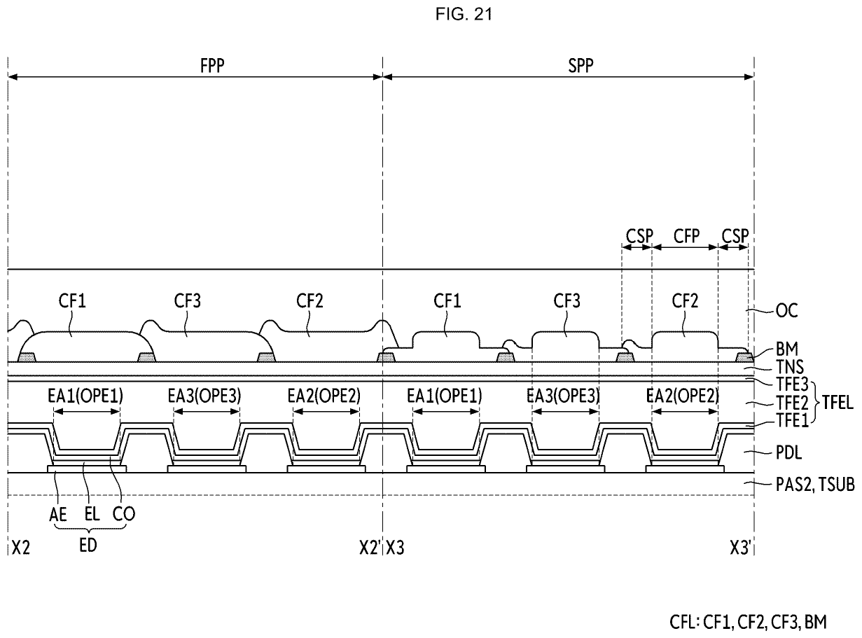

Next, referring to FIG. 21, the third color material layer CFM3 may be developed to form or provide the second color filter CF2 on the second emission area EA2 of the second area SPP. In one or more embodiments, an area that corresponds to the transmissive area MA of the third mask MSK3 may not be removed by a developing solution but formed or provided as the first portion CFP of the second color filter CF2, an area that corresponds to the semi-transmissive area MB may be partially removed by the developing solution and thus formed or provided as the second portion CSP of the second color filter CF2, and an area that corresponds to the light blocking area MC may be fully (e.g., substantially fully) removed by the developing solution.

In one or more embodiments, the first color filter CF1, the second color filter CF2, and the third color filter CF3 may be in the first area FPP of the target substrate TSUB, and the first color filter CF1, the second color filter CF2, and the third color filter CF3 including a first portion CFP and a second portion CSP may be in the second area SPP. Therefore, the color filter layer CFL may be on the touch sensing layer TSU. In one or more embodiments, the first color filter CF1, the second color filter CF2, and the third color filter CF3 in the second area SPP may have thicknesses substantially the same as those of the first color filter CF1, the second color filter CF2, and the third color filter CF3 in the first area FPP, whereby a luminance difference between the first area FPP and the second area SPP of the display device 10 may be substantially resolved.

Finally, an overcoat layer OC may be on the color filter layer CFL, whereby the display device 10 according to one or more embodiments may be fabricated.

In one or more embodiments, it has been described that a separate color filter process may be performed for the first area FPP and the second area SPP of the target substrate TSUB, but embodiments of the present disclosure are not limited thereto. In one or more embodiments, the color material may be concurrently (e.g., simultaneously) coated onto the first area FPP and the second area SPP of the target substrate TSUB. For example, the color material may be coated by an inkjet printing method and the discharge amount of the color material from a nozzle that corresponds to the second area SPP may be increased, so that the color material layers in the first area FPP and the second area SPP may be formed or provided to have substantially the same thickness.

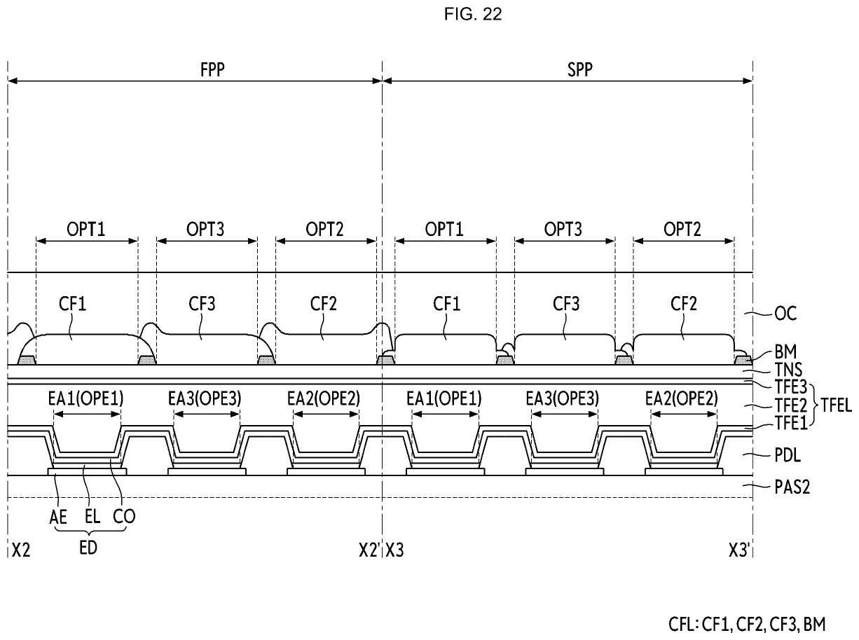

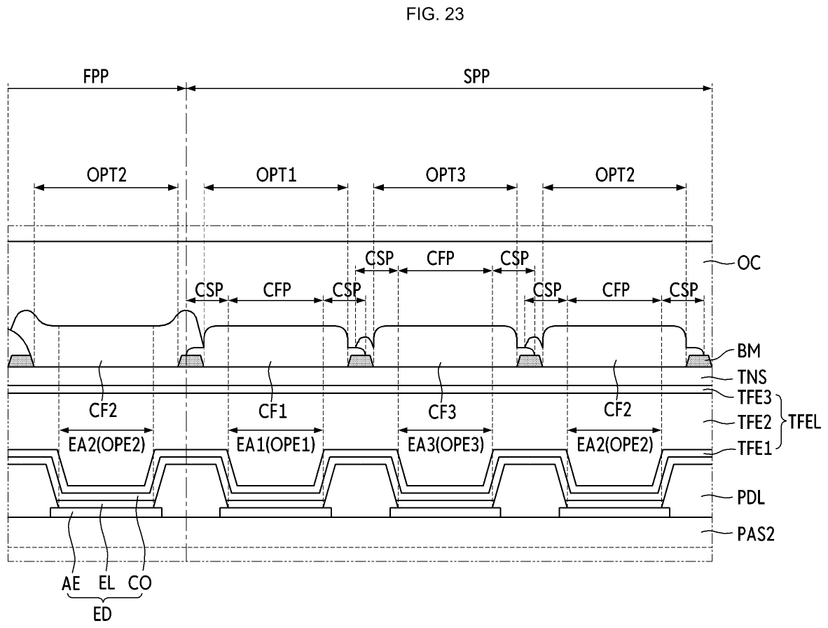

FIG. 22 is a schematic cross-sectional view illustrating a display device according to one or more embodiments. FIG. 23 is a view illustrating a second light emission area of a first area and a first light emission area, a second light emission area, and a third light emission area of a second area in a display area of FIG. 22.

Certain embodiments as illustrated in FIGS. 22 and 23 may be different from one or more embodiments as illustrated in FIGS. 11 to 14 in that the first portions CFP of the color filters CF1, CF2, and CF3 in the second area SPP correspond to the light output portions OPT1, OPT2, and OPT3. Hereinafter, the redundant description of the foregoing embodiments will not be provided, and differences from the foregoing embodiments will be mainly or predominantly described.

Each of the color filters CF1, CF2, and CF3 in the second area SPP may include a first portion CFP and a second portion CSP. The first portion CFP may overlap each of the light emission areas EA1, EA2, and EA3 and may overlap the light output portions OPT1, OPT2, and OPT3. For example, a side of the first portion CFP may be substantially aligned with and substantially matched with sides of light blocking patterns BM adjacent thereto. The first color filter CF1 will be described by way of example. One side (e.g., a left side in the drawing) of the first portion CFP that overlaps the first light emission area EA1 may be substantially aligned with and substantially matched with one side (e.g., a right side in the drawing) of the light blocking pattern BM adjacent thereto. In one or more embodiments, the other side (e.g., a right side in the drawing) of the first portion CFP of the first color filter CF1 that overlaps the first light emission area EA1 may be substantially aligned with and substantially matched with one side (e.g., a left side in the drawing) of the light blocking patterns BM adjacent thereto.

In one or more embodiments, the first portion CFP of each of the color filters CF1, CF2, and CF3 in the second area SPP may not overlap the light blocking pattern BM adjacent thereto and may overlap the pixel defining layer PDL. The first portion CFP of each of the color filters CF1, CF2, and CF3 in the second area SPP may correspond to and be substantially matched with each of the light output portions OPT1, OPT2, and OPT3 of the light blocking pattern BM in which each of the color filters CF1, CF2, and CF3 is arranged or provided. For example, the first color filter CF1 may correspond to the first light output portion OPT1 and thus may have substantially the same size as that of the first light output portion OPT1 on a plane, the second color filter CF2 may correspond to the second light output portion OPT2 and thus may have substantially the same size as that of the second light output portion OPT2 on a plane, and the third color filter CF3 may correspond to the third light output portion OPT3 and thus may have substantially the same size as that of the third light output portion OPT3 on a plane.

The second portion CSP of each of the color filters CF1, CF2, and CF3 in the second area SPP may not overlap each of the light emission areas EA1, EA2, and EA3 and may not overlap each of the light output portions OPT1, OPT2, and OPT3 of the light blocking pattern BM. The second portion CSP of each of the color filters CF1, CF2, and CF3 in the second area SPP may overlap the light blocking pattern BM and the pixel defining layer PDL.

Light emitted from each of the light emission areas EA1, EA2, and EA3 in the second area SPP may be substantially output to the user through each of the light output portions OPT1, OPT2, and OPT3. Therefore, the first portion CFP of each of the color filters CF1, CF2, and CF3 may be formed or provided to correspond to each of the light output portions OPT1, OPT2, and OPT3, and a first thickness T1 of the first portion CFP may be formed or provided to be substantially the same as a thickness FT of each of the color filters CF1, CF2, and CF3 in the first area FPP, whereby the luminance difference between the first area FPP and the second area SPP of the display device 10 may be substantially resolved.

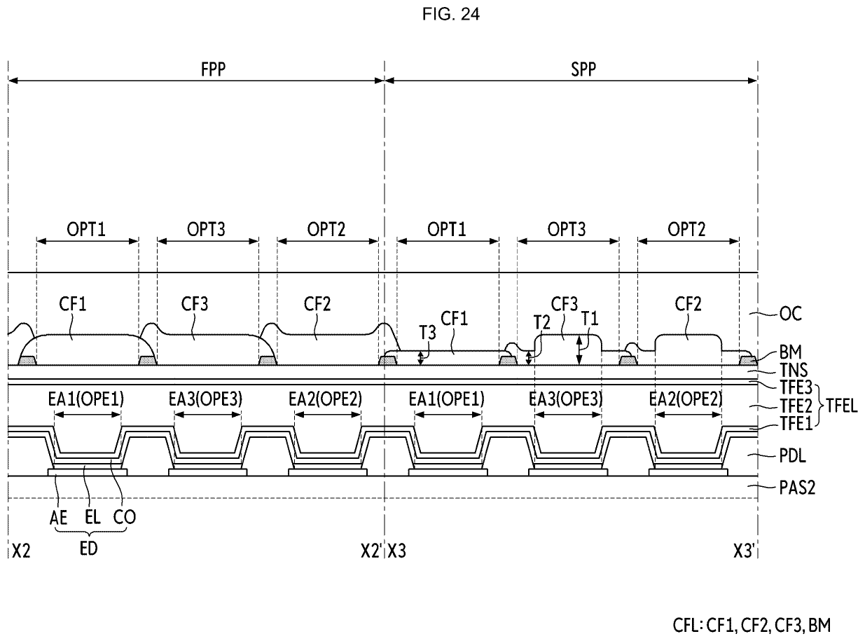

FIGS. 24 to 27 each is a schematic cross-sectional view illustrating examples of a display device according to one or more embodiments.

1 Certain embodiments as illustrated in FIGS. 24 to 27 may be different from one or more embodiments as illustrated in FIGS. 11 to 14, 22, and 23 in that a thickness of one selected from among the color filters CF1, CF2, and CF3 of the second area SPP may be different from that of another one thereof.

Referring to FIG. 24, in one or more embodiments, in order to improve or enhance a color in the second area SPP, the first color filter CF1 may be formed or provided to have a thickness smaller than a thickness of each of the second color filter CF2 and the third color filter CF3.

In more detail, each of the second color filter CF2 and the third color filter CF3 of the second area SPP may include a first portion CFP and a second portion CSP. The first color filter CF1 may not include the first portion CFP and the second portion CSP, so that the first color filter CF1 may be formed or provided to have a substantially uniform thickness as a whole. The first portion CFP of each of the second color filter CF2 and the third color filter CF3 may have a first thickness T1, and the second portion CSP may have a second thickness T2 smaller than the first thickness T1, wherein the first thickness T1 may be substantially the same as the thickness of each of the color filters CF1, CF2, and CF3 of the first area FPP.

According to one or more embodiments, a thickness T3 of the first color filter CF1 of the second area SPP may be smaller than the thickness T1 of the first portion CFP of each of the second color filter CF2 and the third color filter CF3. For example, the thickness T1 of the first portion CFP of the second color filter CF and/or the thickness T1 of the first portion CFP of the third color filter CF3 may be greater than the thickness T3 of the first color filter CF1.

In the second area SPP, a white color may be shifted to a set or specific portion on a color coordinate. For example, if (e.g., when) it is necessary to shift the white color toward a red color in the second area SPP, the thickness T3 of the first color filter CF1, which is a red color filter, may be formed or provided to be smaller than the thickness T1 of the first portion CFP of each of the second color filter CF2 and the third color filter CF3. In one or more embodiments, efficiency of red light may be increased or enhanced. Therefore, the white color of the second area SPP may be shifted toward the red color, so that the white color may be improved or enhanced.

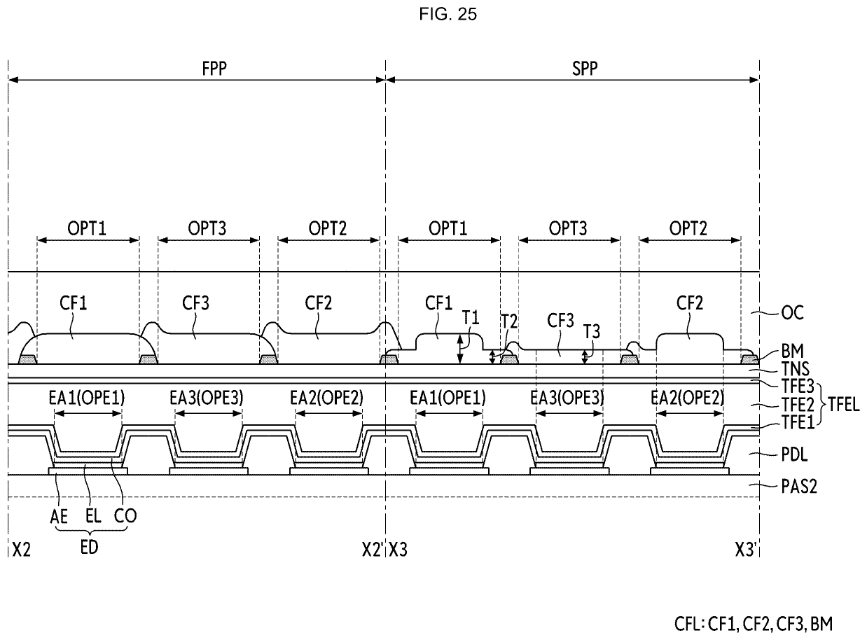

Also, referring to FIG. 25, each of the first color filter CF1 and the second color filter CF2 of the second area SPP may include a first portion CFP and a second portion CSP. The third color filter CF3 may be formed or provided to have a substantially uniform thickness as a whole. The first portion CFP of each of the first color filter CF1 and the second color filter CF2 may have a first thickness T1, and the second portion CSP thereof may have a second thickness T2 smaller than the first thickness T1, wherein the first thickness T1 may be substantially the same as the thickness of each of the color filters CF1, CF2, and CF3 of the first area FPP.

The thickness T3 of the third color filter CF3 of the second area SPP may be smaller than the thickness T1 of the first portion CFP of each of the first color filter CF1 and the third color filter CF3. If (e.g., when) it is necessary to shift the white color toward a green color in the second area SPP, the thickness T3 of the third color filter CF3, which is a green color filter, may be formed or provided to be smaller than the thickness T1 of the first portion CFP of each of the first color filter CF1 and the second color filter CF2. In one or more embodiments, efficiency of green light may be increased or enhanced. Therefore, the white color of the second area SPP may be shifted toward the green color, so that the white color may be improved or enhanced.

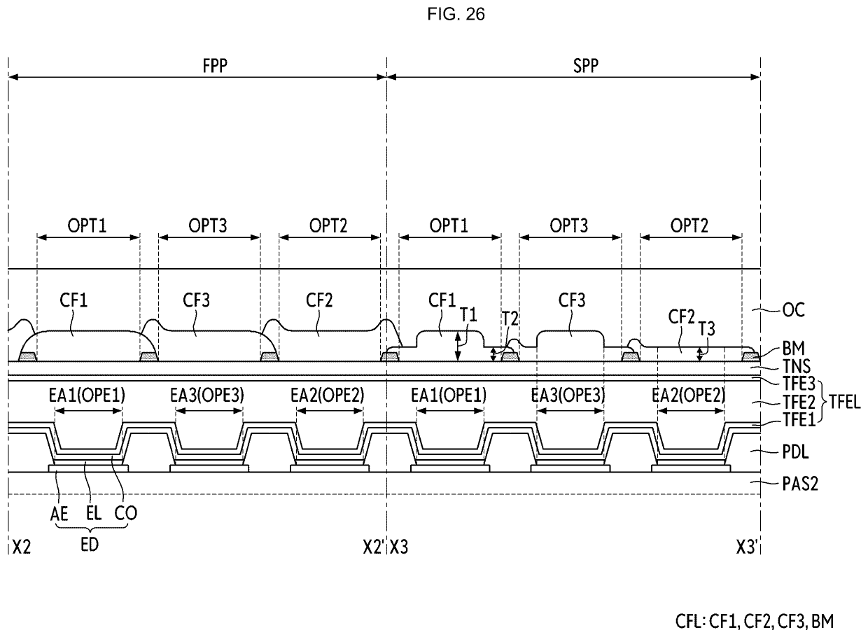

Also, referring to FIG. 26, each of the first color filter CF1 and the third color filter CF3 of the second area SPP may include a first portion CFP and a second portion CSP. The second color filter CF2 may be formed or provided to have a substantially uniform thickness as a whole. The first portion CFP of each of the first color filter CF1 and the third color filter CF3 may have a first thickness T1, and the second portion CSP thereof may have a second thickness T2 smaller than the first thickness T1, wherein the first thickness T1 may be substantially the same as the thickness of each of the color filters CF1, CF2, and CF3 of the first area FPP.

The thickness T3 of the second color filter CF2 of the second area SPP may be smaller than the thickness T1 of the first portion CFP of each of the first color filter CF1 and the third color filter CF3. If (e.g., when) it is necessary to shift the white color toward a blue color in the second area SPP, the thickness T3 of the second color filter CF2, which is a blue color filter, may be formed or provided to be smaller than the thickness T1 of the first portion CFP of each of the first color filter CF1 and the third color filter CF3. In one or more embodiments, efficiency of blue light may be increased or enhanced. Therefore, the white color of the second area SPP may be shifted toward the blue color, so that the white color may be improved or enhanced.

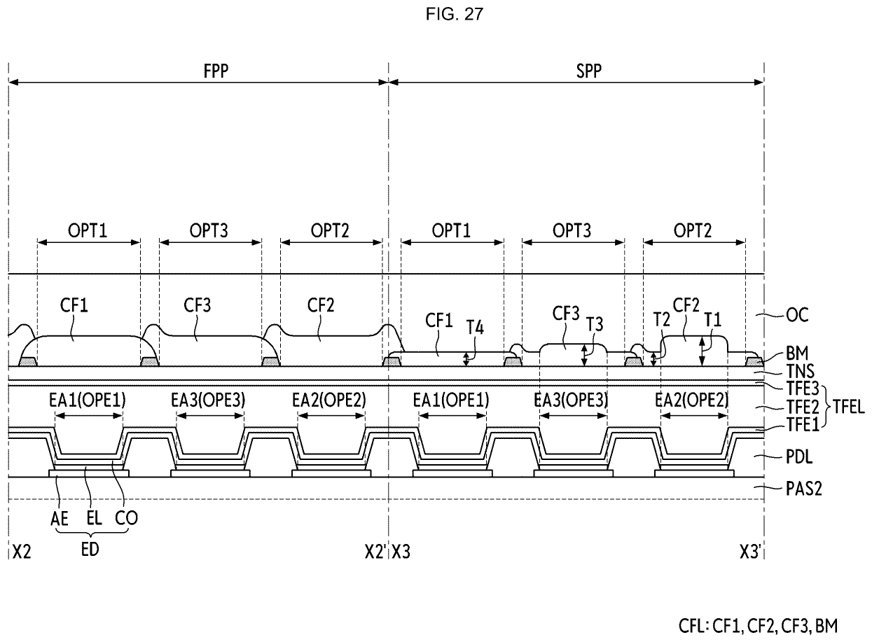

Also, as illustrated in FIG. 27, each of the second color filter CF2 and the third color filter CF3 of the second area SPP may include a first portion CFP and a second portion CSP. The first color filter CF1 may be formed or provided to have a substantially uniform thickness as a whole. The first portion CFP of the second color filter CF2 may have a first thickness T1, and the first thickness T1 of the first portion CFP of the second color filter CF2 may be greater than the third thickness T3 of the first portion CFP of the third color filter CF3. A fourth thickness T4 of the first color filter CF1 may be smaller than the third thickness T3 of the first portion CFP of the third color filter CF3. The first thickness T1 of the first portion CFP of the second color filter CF2 may be substantially the same as the thickness of each of the color filters CF1, CF2, and CF3 of the first area FPP.

If (e.g., when) it is necessary to shift the white color toward the green color and further toward the red color in the second area SPP, the third thickness T3 of the first portion CFP of the third color filter CF3, which is a green color filter, may be formed or provided to be smaller than the first thickness T1 of the first portion CFP of the second color filter CF2 and the fourth thickness T4 of the first portion CFP of the first color filter CF1, which is a red color filter, may be formed or provided to be smaller than the third thickness T3 of the first portion CFP of the third color filter CF3. In one or more embodiments, efficiency of green light and red light may be increased or enhanced. Therefore, the white color of the second area SPP may be shifted toward the green color and the red color, so that the white color may be improved or enhanced.

In one or more embodiments, the thicknesses of the color filter CF1, CF2, and CF3 of the second area SPP may be differentially applied, so that the white color of the second area SPP may be more precisely improved or enhanced.

Table 1 shows the results of checking the variation in efficiency of white, red, green, and blue colors according to the decrease in thicknesses of first to third color filters R CF, G CF, and B CF in the entire area of the display device. The thickness of the color filter was reduced by 0.1 μm, and two display devices were respectively tested using different color filter materials. The parentheses refers to the ratio of increased efficiency.

TABLE 1

| | | White | Red | Green | Blue |
|---|---|---|---|---|---|
| | | efficiency | efficiency | efficiency | efficiency |
| | | variation | variation | variation | variation |
| | | value (cd/A) | value (cd/A) | value (cd/A) | value (cd/A) |
| #1 | R CF | 0.5(+0.7%) | 2(+2.6%) | — | — |
| | G CF | 1(+1.4%) | — | 4(+2.3%) | — |
| | B CF | 1(+1.4%) | — | — | 6(+3%) |
| #2 | R CF | 0.5(+0.7%) | 2(+2.6%) | — | — |
| | G CF | 1(+1.4%) | — | 6(+3.5%) | — |
| | B CF | 1(+1.4%) | — | — | 6(+3%) |

Referring to Table 1, when the thickness of each of the color filters R CF, G CF, and B CF was reduced by 0.1 μm, the efficiency of light emitted through the color filter having the reduced thickness was increased and the white efficiency was also increased.

Through this result, it can be noted from one or more embodiments disclosed in the drawings that the thickness of each of the color filters in the second area SPP may be formed or provided to be substantially the same as the thickness of each of the color filters in the first area FPP to improve or enhance the white color between the second area SPP and the first area FPP, and the thicknesses of the color filters in the second area SPP may be formed or provided differently to improve or enhance the white color in the second area SPP.

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

The utilization of “may” if (e.g., when) describing embodiments of the present disclosure refers to “one or more embodiments of the present disclosure.”

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within +30%, +20%, +10%, or +5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light-emitting element, the display apparatus/device, the electronic apparatus/device, the manufacturing apparatuses thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the one or more suitable components of the device may be formed or provided on one integrated circuit (IC) chip or on separate IC chips. Further, the one or more suitable components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components to perform the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the present disclosure, each suitable feature of the one or more embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

While the present disclosure has been described with reference to one or more embodiments thereof, those skilled in the art will appreciate that one or more suitable variations and modifications may be made to the embodiments without substantially departing from the spirit and scope of the present disclosure as set forth in the following claims and equivalents thereof. Therefore, the disclosed embodiments of present disclosure are used in a generic and descriptive sense only and not for purposes of limitation.

What is claimed is:

1. A display device, comprising:
a display area comprising a first area and a second area around the first area;
a non-display area around the display area;
a light emitting element layer, on the display area, comprising a pixel defining layer that partitions light emission areas; and
a color filter layer, in the first area and the second area on the light emitting element layer, comprising color filters and a light blocking pattern,
wherein at least one selected from among the color filters in the second area comprises a first portion protruded to overlap the light emission areas and a second portion around the first portion, and
a thickness of an area of the color filters in the first area, which overlaps the light emission areas, is substantially the same as a thickness of the first portion.

2. The display device as claimed in claim 1, wherein the first area corresponds to a central portion of the display area, and the second area corresponds to an edge of the display area.

3. The display device as claimed in claim 2, wherein a width of the second area, which is measured in one direction, is about 1% to about 8% of a width of the display area, which is measured in the one direction.

4. The display device as claimed in claim 1, wherein the first portion is more protruded than the second portion in a thickness direction, and the thickness of the first portion is greater than a thickness of the second portion.

5. The display device as claimed in claim 1, wherein the first portion does not overlap the pixel defining layer and the light blocking pattern.

6. The display device as claimed in claim 1, wherein the second portion does not overlap the light emission areas, and overlaps the pixel defining layer and the light blocking pattern.

7. The display device as claimed in claim 1, wherein each of the color filters in the second area comprises the first portion and the second portion, and each of the first portions has substantially the same thickness.

8. The display device as claimed in claim 1, wherein
the light blocking pattern partitions light output portions that correspond to the light emission areas,
the first portion overlaps the light output portions, and
the second portion does not overlap the light output portions.

9. The display device as claimed in claim 1, wherein the first portion overlaps the pixel defining layer, and does not overlap the light blocking pattern, and wherein the second portion overlaps the light blocking pattern and the pixel defining layer.

10. The display device as claimed in claim 1, wherein the at least one selected from among the color filters in the second area is different in thickness from another one selected from among the color filters in the second area.

11. The display device as claimed in claim 10, wherein
the color filters in the second area comprise a first color filter, a second color filter, and a third color filter, which are to transmit light of different colors,
each of the second color filter and the third color filter comprises the first portion and the second portion, and
the first color filter does not comprise the first portion and the second portion.

12. The display device as claimed in claim 11, wherein a thickness of either the first portion of the second color filter or the first portion of the third color filter is greater than a thickness of the first color filter.

13. The display device as claimed in claim 12, wherein the thickness of the first portion of the second color filter and the thickness of the first portion of the third color filter are substantially the same as each other.

14. The display device as claimed in claim 11, wherein a thickness of the first portion of the second color filter is greater than a thickness of the first portion of the third color filter.

15. A display device, comprising:
a display area comprising a first area and a second area around the first area;
a non-display area around the display area;
a light emitting element layer on the display area; and
a color filter layer, in the first area and the second area on the light emitting element layer, comprising color filters and a light blocking pattern,
wherein the light blocking pattern partitions light output portions through which light is output from the light emitting element layer,
at least one selected from among the color filters in the second area comprises a first portion that overlaps the light output portions and a second portion that has a thickness smaller than a thickness of the first portion, and
a thickness of an area of the color filters in the first area, which overlaps the light output portions, is substantially the same as the thickness of the first portion.

16. The display device as claimed in claim 15, wherein the first portion does not overlap the light blocking pattern, and the second portion overlaps the light blocking pattern.

17. The display device as claimed in claim 15, wherein the first area corresponds to a central portion of the display area, and the second area corresponds to an edge of the display area.

18. The display device as claimed in claim 15, wherein each of the color filters in the second area comprises the first portion and the second portion, and each of the first portions has substantially the same thickness.

19. An electronic device, comprising a display device comprising:
a display area comprising a first area and a second area around the first area;
a non-display area around the display area;
a light emitting element layer on the display area, comprising a pixel defining layer that partitions light emission areas; and
a color filter layer in the first area and the second area on the light emitting element layer, comprising color filters and a light blocking pattern,
wherein at least one selected from among the color filters in the second area comprises a first portion protruded to overlap the light emission areas and a second portion around the first portion, and
a thickness of an area of the color filters in the first area, which overlaps the light emission areas, is substantially the same as a thickness of the first portion.

20. The electronic device as claimed in claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
